(19) United States
(12) Patent Application Publication
(10) Pub. No.: US 2024/0120199 A1
(43) Pub. Date: Apr. 11, 2024

(54) METHOD FOR MANUFACTURING SEMICONDUCTOR DEVICE

(71) Applicant: SAMSUNG ELECTRONICS CO., LTD., Suwon-si (KR)

(72) Inventors: So Young LEE, Suwon-si (KR); Yun Hee KIM, Suwon-si (KR)

(21) Appl. No.: 18/244,376

(22) Filed: Sep. 11, 2023

(30) Foreign Application Priority Data
Oct. 11, 2022 (KR) 10-2022-0129820
Apr. 10, 2023 (KR) 10-2023-0046764

(51) Int. Cl. H01L 21/033; G03F 7/00; H01L 23/544; H10B 12/00; H10B 43/27

(52) U.S. Cl. CPC H01L 21/0337; G03F 7/70633; H01L 23/544; H10B 12/033; H10B 43/27; H01L 2223/54426

(57) ABSTRACT

A method for manufacturing a semiconductor device, including forming a step key on a substrate, forming a mold layer on the step key covering the step key, forming a first mask layer on the mold layer, forming a transparent layer in the first mask layer overlapping the step key, forming a second mask layer on the first mask layer and the transparent layer, etching the mold layer using the second mask layer, wherein the first mask layer includes a metal material.

### CROSS-REFERENCE TO RELATED APPLICATION

Korean Patent Application No. 10-2022-0129820 filed on Oct. 11, 2022, and No. 10-2023-0046764 filed on Apr. 10, 2023, in the Korean Intellectual Property Office is herein incorporated by reference in its entirety.

### BACKGROUND

### 1. Field

A method for manufacturing a semiconductor device with improved overlay measurement accuracy is disclosed.

### 2. Description of Related Art

As a semiconductor device is highly integrated, a line width of a pattern included in the semiconductor device is getting finer, and complex processes and novel materials are applied to a manufacturing process such that difficulty in a measurement process is also increasing.

### SUMMARY

Embodiments are directed to a method for manufacturing a semiconductor device, including forming a step key on a substrate, forming a mold layer on the step key covering the step key, forming a first mask layer on the mold layer, forming a transparent layer in the first mask layer overlapping the step key, forming a second mask layer on the first mask layer and the transparent layer, etching the mold layer using the second mask layer, wherein the first mask layer includes a metal material.

Embodiments are directed to a method for manufacturing a semiconductor device, including forming a substrate including a chip area and an out-of-chip area, forming a step key on the out-of-chip area of the substrate, forming a mold layer on the substrate covering the step key, forming a first mask layer on the mold layer, forming a key-hole in the first mask layer overlapping the step key, forming a transparent layer in the key-hole, forming a second mask layer on the first mask layer and the transparent layer while aligning the second mask layer using the step key, etching the mold layer using the second mask layer to form a pattern hole, and filling the pattern hole with a pattern material to form a pillar structure.

Embodiments are directed to a method for manufacturing a semiconductor device, including forming a substrate including a chip area and an out-of-chip area, forming a bit line on the substrate and in the chip area extending across the substate, forming a buried contact between the bit lines and connected to the chip area of the substrate, forming a landing pad on the buried contact, forming a step key on the substrate and in the out-of-chip area, forming a mold layer on the chip area and the out-of-chip area covering the landing pad and the step key, forming a first mask layer on the mold layer, wherein the first mask layer includes a metal material, forming a key-hole in the first mask layer overlapping the step key, forming a transparent layer in the key-hole, forming a second mask layer on the first mask layer and the transparent layer while aligning the second mask layer using the step key, etching the mold layer in the chip area using the second mask layer to form a pattern hole, forming a lower electrode filling the pattern hole, and forming a dielectric film and an upper electrode on the lower electrode, a light transmittance of the transparent layer being greater than a light transmittance of the first mask layer, and a first vertical level of an upper surface of the lower electrode extending farther in a vertical direction relative to a bottom surface of the substrate than a second vertical level of an upper surface of the mold layer.

### BRIEF DESCRIPTION OF DRAWINGS

Features will become apparent to those of skill in the art by describing in detail exemplary embodiments with reference to the attached drawings in which:

FIG. 1 to FIG. 12 are diagrams showing stages in a method for manufacturing a semiconductor device according to example embodiments.

FIG. 13 to FIG. 15 are diagrams showing stages in a method for manufacturing a semiconductor device according to example embodiments.

FIG. 16 to FIG. 18 are diagrams showing stages in a method for manufacturing a semiconductor device according to example embodiments.

FIG. 19 to FIG. 26 are diagrams showing stages in a method for manufacturing a semiconductor device according to example embodiments.

FIG. 27 to FIG. 29 are diagrams showing stages in a method for manufacturing a semiconductor device according to example embodiments.

FIG. 30 to FIG. 32 are diagrams showing stages in a method for manufacturing a semiconductor device according to example embodiments.

FIG. 33 is a diagram showing a stage in a method for manufacturing a semiconductor device according to example embodiments.

FIG. 34 to FIG. 39 are diagrams showing stages in a method for manufacturing a semiconductor device according to example embodiments.

FIG. 40 to FIG. 45 are diagrams showing stages in a method for manufacturing a semiconductor device according to example embodiments.

FIG. 46 to FIG. 54 are diagrams showing stages in a method for manufacturing a semiconductor device according to example embodiments.

FIG. 55 to FIG. 64 are diagrams showing a semiconductor device manufactured using a method for manufacturing a semiconductor device according to example embodiments.

FIG. 65 to FIG. 70 are diagrams showing a semiconductor device manufactured using a method for manufacturing a semiconductor device according to example embodiments.

### DETAILED DESCRIPTION

Hereinafter, embodiments according to the technical idea of the present disclosure will be described with reference to the accompanying drawings.

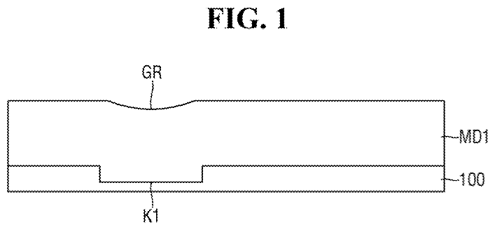

FIG. 1 to FIG. 12 are diagrams showing intermediate structures respectively corresponding to intermediate steps of a method for manufacturing a semiconductor device according to example embodiments. Referring to FIG. 1, a first step key K1 and a first mold layer MD1 may be on a substrate 100.

The first step key K1 may include a trench recessed towards a lower surface of substrate 100. In an implementation, the first step key K1 may have a step from an upper surface of substrate 100 towards the lower surface of substrate 100.

The first mold layer MD1 may be on the substrate 100. The first mold layer MD1 may be on the first step key K1 including the trench. The first mold layer MD1 may cover the first step key K1. The first mold layer MD1 is illustrated as being a single layer. In an implementation, the first mold layer MD1 may include a plurality of films.

The first mold layer MD1 may have a curved upper surface in an area overlapping the first step key K1. In an implementation, the first mold layer MD1 may have a groove GR overlapping the first step key K1. As the first step key K1 has the trench recessed toward the lower surface of the substrate 100, the upper surface of the first mold layer MD1 may be recessed toward the substrate 100 in the area overlapping the first step key K1.

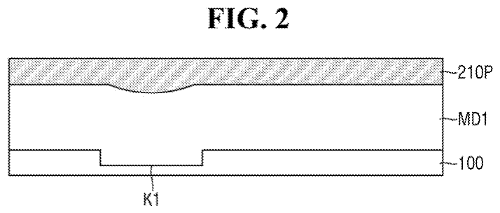

Referring to FIG. 2, a first pre-mask layer 210P may be on the first mold layer MD1. The first pre-mask layer 210P may extend along the upper surface of the first mold layer MD1. The first pre-mask layer 210P may cover the first mold layer MD1.

The first pre-mask layer 210P may include a metal material. In an implementation, the first pre-mask layer 210P may include a material doped with metal. In some embodiments, the first pre-mask layer 210P may include aluminum (Al), titanium (Ti), chromium (Cr), nickel (Ni), copper (Cu), zirconium (Zr), molybdenum (Mo), ruthenium (Ru), hafnium (Hf), tantalum (Ta), tungsten (W), platinum (Pt), or lanthanum (La) or an alloy of the above materials. The first pre-mask layer 210P may be opaque. As used herein, the term “or” is not an exclusive term, e.g., “A or B” would include A, B, or A and B.

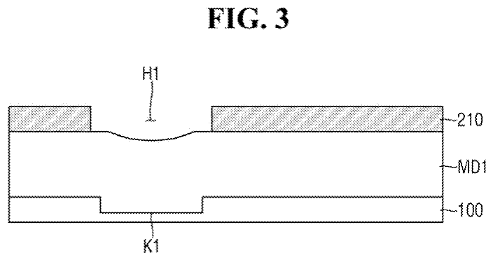

The first pre-mask layer 210P may have a higher etch selectivity with respect to that of the first mold layer MD1. When the first mold layer MD1 is etched into a pattern having a high aspect ratio, the first mold layer MD1 may be stably etched using the first pre-mask layer 210P having the higher etching selectivity relative to that of the first mold layer MD1. The first pre-mask layer 210P may have lower light transmittance than that of the first mold layer MD1. Referring to FIG. 3, a key-hole H1 may be in the first mask layer 210.

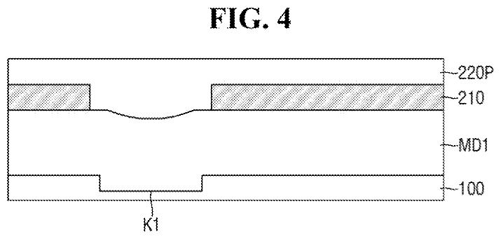

The key-hole H1 may extend through the first mask layer 210. The key hole H1 may overlap with the first step key K1. The key-hole H1 may expose the upper surface of the first mold layer MD1. The key-hole H1 may expose the curved surface of the first mold layer MD1. The key-hole H1 may expose the groove (GR in FIG. 1) of the upper surface of the first mold layer MD1. Referring to FIG. 4, a pre-transparent layer 220P may be on the first mask layer 210.

The pre-transparent layer 220P may cover the first mask layer 210. The pre-transparent layer 220P may fill the key-hole H1 in FIG. 3. An upper surface of the pre-transparent layer 220P may be positioned at a higher level than that of the upper surface of the first mask layer 210.

The pre-transparent layer 220P may include hafnium oxide (HfO₂), titanium oxide (TiO₂), tantalum oxide (TaO₂), silicon oxide (SiO₂) or silicon nitride (Si₃N₄). Light transmittance of the pre-transparent layer 220P may be greater than light transmittance of the first mask layer 210. An extinction coefficient and a refractive index of the pre-transparent layer 220P may be lower than an extinction coefficient and a refractive index of the first mask layer 210, respectively. The pre-transparent layer 220P may be formed through CVD (chemical vapor deposition), PVD (physical vapor deposition), or ALD (atomic layer deposition).

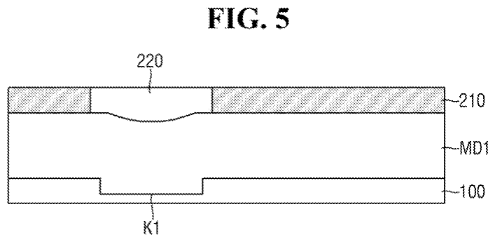

Referring to FIG. 5, a transparent layer 220 may be in the first mask layer 210. The upper surface of the first mask layer 210 may be exposed by removing the pre-transparent layer 220P in FIG. 4 covering the upper surface of the first mask layer 210. An upper surface of the transparent layer 220 may be coplanar with the upper surface of the first mask layer 210. The transparent layer 220 may fill the key-hole (H1 in FIG. 3) in the first mask layer 210. The transparent layer 220 may overlap the first step key K1. The transparent layer 220 may be surrounded with the first mask layer 210. A sidewall of the transparent layer 220 may be covered with the first mask layer 210. A width of the transparent layer 220 may be greater than or equal to a width of the first step key K1. A portion of the pre-transparent layer (220P in FIG. 4) on top of the upper surface of the first mask layer 210 may be removed through CMP (chemical mechanical polishing).

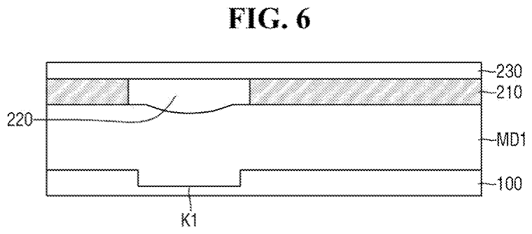

Referring to FIG. 6, a second mask layer 230 may be on the first mask layer 210 and the transparent layer 220. The second mask layer 230 may extend along the upper surfaces of the first mask layer 210 and the transparent layer 220. The second mask layer 230 may cover the first mask layer 210 and the transparent layer 220.

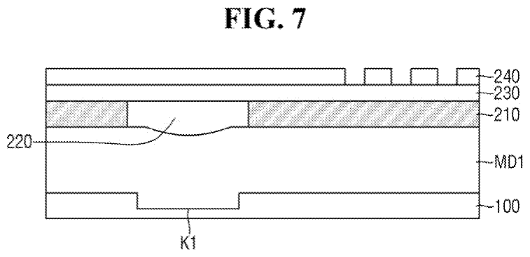

The second mask layer 230 may include silicon oxide or silicon nitride. The second mask layer 230 is illustrated as being a single layer. In an implementation, the second mask layer 230 may include a plurality of films. Referring to FIG. 7, a third mask layer 240 may be on the second mask layer 230.

The third mask layer 240 may cover the second mask layer 230. The third mask layer 240 may include photoresist. The third mask layer 240 may include a pattern for etching the first mold layer MD1. The third mask layer 240 may have the pattern exposing a portion of an upper surface of the second mask layer 230. The third mask layer 240 may have the pattern so as not to cover the portion of the upper surface of the second mask layer 230.

The third mask layer 240 may be aligned using the first step key K1. Whether the pattern of the third mask layer 240 for etching the first mold layer MD1 overlies at a target position may be determined using the first step key K1.

In an implementation, to determine whether the third mask layer 240 is aligned correctly, light may be irradiated onto the first step key K1. Whether the third mask layer 240 is aligned correctly may be determined based on a result of detecting a polarization state and diffraction of the light irradiated to the first step key K1.

The first mask layer 210 including the metal material may have low light transmittance. Therefore, the first mask layer 210 may be on the first step key K1. Thus, even though the light is irradiated to determine whether the third mask layer 240 is aligned correctly, it may not be easy to detect the polarization state and the diffraction of the light using the first step key K1. Alternatively, the transparent layer 220 may overlap the first step key K1. In this case, since the transparent layer 220 has higher light transmittance than that of the first mask layer 210, it may be easily determined whether the third mask layer 240 is aligned correctly based on the result of detecting the polarization state and the diffraction of the light irradiated toward the first step key K1.

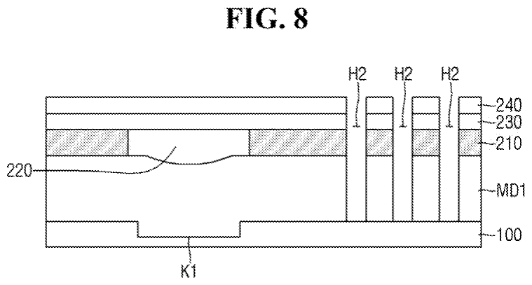

Referring to FIG. 8, the first mold layer MD1 may be etched using the third mask layer 240. A pattern hole H2 may be in the first mold layer MD1, the first mask layer 210, and the second mask layer 230 using the pattern of the third mask layer 240. The pattern hole H2 may extend through the first mold layer MD1 and the first mask layer 210. Using the first step key K1, the pattern hole H2 may be at a target location on the substrate 100.

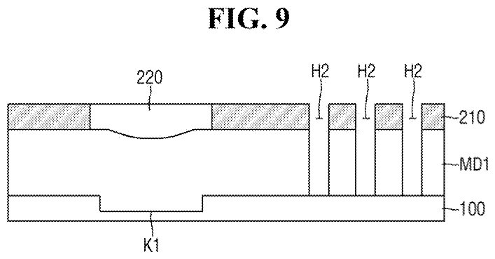

Referring to FIG. 9, the second mask layer 230 and the third mask layer 240 may be removed. The first mask layer 210 and the transparent layer 220 may be exposed. The pattern hole H2 may be in the first mold layer MD1 and the first mask layer 210.

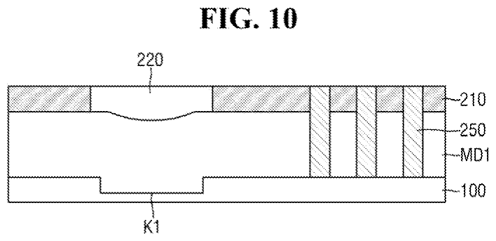

Referring to FIG. 10, a pillar structure 250 may be formed. The pillar structure 250 may be in the pattern hole (H2 in FIG. 9). The pillar structure 250 may fill the pattern hole (H2 in FIG. 9). A pattern material may fill the pattern hole (H2 in FIG. 9). An upper surface of the pillar structure 250 may be coplanar with the upper surface of the first mask layer 210. Based on the lower surface of the substrate 100, the upper surface of the pillar structure 250 may be positioned at a higher level than that of the upper surface of the first mold layer MD1.

In an implementation, the pillar structure 250 may include a lower electrode of a DRAM capacitor. In another example, the pillar structure 250 may include a channel structure of a non-volatile memory such as NAND. In still another example, the pillar structure 250 may include a through-via.

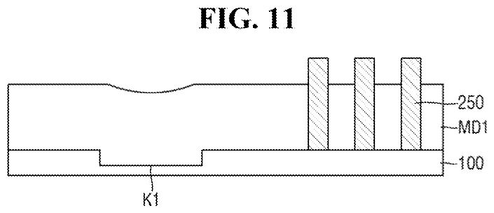

Referring to FIG. 11, the first mask layer 210 and the transparent layer 220 may be removed. The upper surface of the first mold layer MD1 may be exposed. As the first mask layer 210 has been removed, a portion of a sidewall of the pillar structure 250 may be exposed. The pillar structure 250 may protrude upwardly beyond the upper surface of the first mold layer MD1.

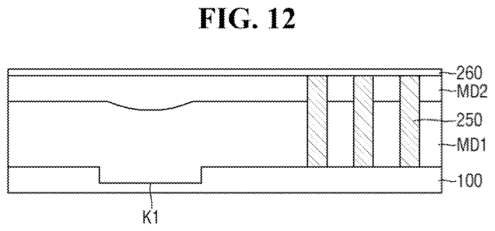

Referring to FIG. 12, a second mold layer MD2 and a protective film 260 may be on the first mold layer MD1. The second mold layer MD2 may surround the portion of the sidewall of the exposed pillar structure 250. The second mold layer MD2 may extend along the upper surface of the first mold layer MD1. The protective film 260 may extend along an upper surface of the second mold layer MD2. The protective film 260 may cover an upper surface of the pillar structure 250.

In an implementation, the second mold layer MD2 may include silicon oxide. The protective film 260 may include silicon nitride. In FIG. 12, each of the second mold layer MD2 and the protective film 260 is shown as a single film. In an implementation, each of the second mold layer MD2 and the protective film 260 may include a plurality of films.

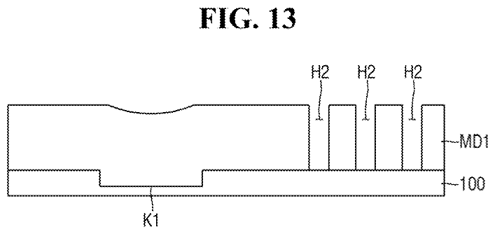

FIG. 13 to FIG. 15 are diagrams showing intermediate structures corresponding to intermediate steps of a method for manufacturing a semiconductor device according to example embodiments.

For the convenience of description, differences from those described with reference to FIG. 1 to FIG. 12 will be mainly described. For reference, FIG. 13 is a diagram showing a step subsequent to FIG. 8.

Referring to FIG. 8 and FIG. 13, after forming the pattern hole H2, the first mask layer 210, the transparent layer 220, the second mask layer 230, and the third mask layer 240 may be removed. The pattern hole H2 may extend only through the first mold layer MD1. The first mask layer 210, the transparent layer 220, the second mask layer 230, and the third mask layer 240 may be removed, such that the upper surface of the first mold layer MD1 may be exposed.

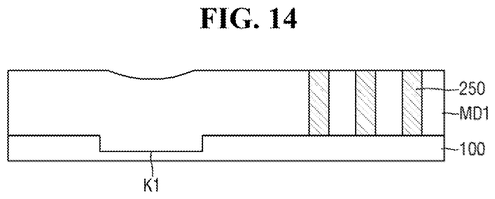

Referring to FIG. 14, the pillar structure 250 may be formed. The pillar structure 250 may be in the pattern hole (H2 of FIG. 13). The pillar structure 250 may fill the pattern hole (H2 in FIG. 13). The upper surface of pillar structure 250 may be coplanar with the upper surface of the first mold layer MD1. An entirety of the sidewall of the pillar structure 250 may be surrounded with the first mold layer MD1.

Referring to FIG. 14 compared to FIG. 10, a vertical dimension of the pillar structure (250 in FIG. 14) may be smaller than that of the pillar structure (250 in FIG. 10).

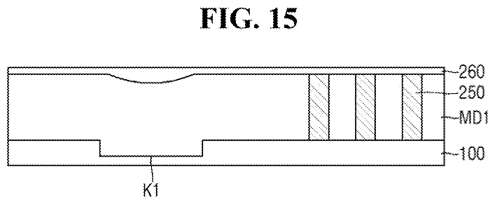

Referring to FIG. 15, the protective film 260 may be formed. The protective film 260 may be on the first mold layer MD1 and the pillar structure 250. The protective film 260 may extend along the upper surface of the first mold layer MD1. The protective film 260 may cover the upper surface of the pillar structure 250.

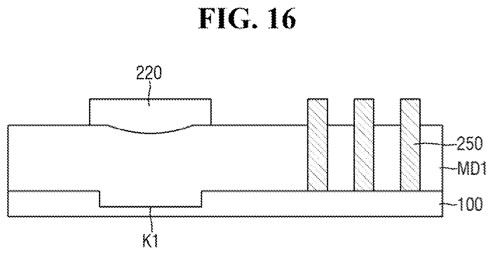

FIG. 16 to FIG. 18 are diagrams showing intermediate structures corresponding to intermediate steps of a method for manufacturing a semiconductor device according to example embodiments.

For the convenience of description, differences from those described with reference to FIG. 1 to FIG. 12 will be mainly described. For reference, FIG. 16 is a diagram showing a step subsequent to FIG. 10. Referring to FIG. 10 and FIG. 16, after forming the pillar structure 250, the first mask layer 210 may be removed.

As the first mask layer 210 has been removed, a sidewall of the transparent layer 220 may be exposed. The pillar structure 250 may protrude upwardly beyond the upper surface of the first mold layer MD1. The transparent layer 220 may be on the first mold layer MD1. The upper surface of the pillar structure 250 and the upper surface of the transparent layer 220 may be coplanar with each other. In an implementation, based on the lower surface of the substrate 100, the upper surface of the pillar structure 250 and the upper surface of the transparent layer 220 may have the same vertical level.

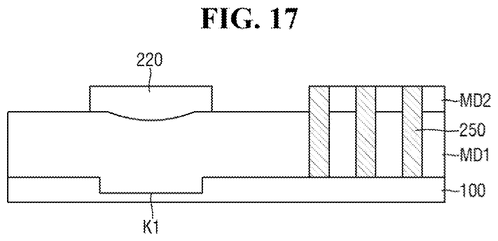

Referring to FIG. 17, the second mold layer MD2 may be formed. The second mold layer MD2 may fill a space between adjacent ones of portions of the pillar structures 250 protruding upwardly beyond the upper surface of the first mold layer MD1. The second mold layer MD2 may be between the pillar structures 250.

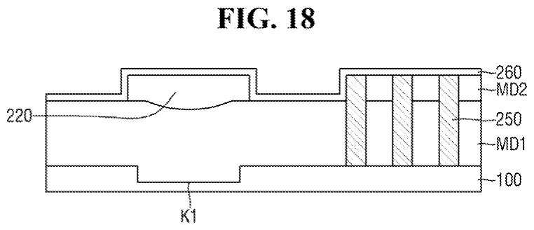

Referring to FIG. 18, the protective film 260 may be formed. The protective film 260 may be on the transparent layer 220, the first mold layer MD1, the pillar structure 250, and the second mold layer MD2. The protective film 260 may extend along profiles of the transparent layer 220, the first mold layer MD1, the pillar structure 250, and the second mold layer MD2.

The protective film 260 may surround the transparent layer 220. The protective film 260 may cover an upper surface and a sidewall of the transparent layer 220. The protective film 260 may cover the upper surface of the pillar structure 250 and the upper surface of the second mold layer MD2.

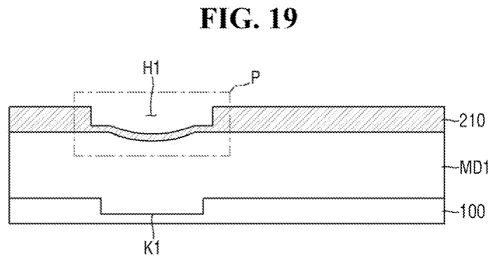

FIG. 19 to FIG. 26 are diagrams showing intermediate structures respectively corresponding to intermediate steps of a method for manufacturing a semiconductor device according to example embodiments.

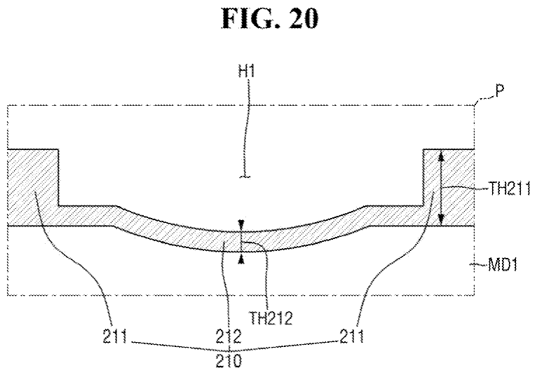

For the convenience of description, differences from those described with reference to FIG. 1 to FIG. 12 will be mainly described. For reference, FIG. 19 is a diagram showing a step subsequent to FIG. 2. FIG. 20 is an enlarged view showing a P portion of FIG. 19.

Referring to FIG. 2, FIG. 19 and FIG. 20, the key-hole H1 may be on the first mask layer 210. The key-hole H1 may extend through only a portion of the first mask layer 210. The key-hole H1 may expose the first mask layer 210. An inner sidewall and a bottom surface of the key-hole H1 may be defined by the first mask layer 210. The key-hole H1 may overlap with the first step key K1.

The first mask layer 210 may include a first portion 211 and a second portion 212. The first portion 211 may be on a side of the key-hole H1. The first portion 211 may define an inner sidewall of the key-hole H1. The first portion 211 may not overlap with the first step key K1.

The second portion 212 may be under the key-hole H1. The second portion 212 may define a bottom surface of the key-hole H1. The second portion 212 may overlap the first step key K1.

A thickness of the second portion 212 may be smaller than a depth of the key-hole H1. In an implementation, a thickness TH212 of the second portion may be smaller than a distance from an upper surface of the second portion 212 to an upper surface of the first portion 211. Based on the lower surface of the substrate 100, a thickness TH211 of the first portion may be greater than the thickness TH212 of the second portion.

The thickness of the second portion 212 may be in a range in which light can transmit through the first mask layer 210. In an implementation, when the first mask layer 210 includes tungsten silicide (WSi), the thickness of the second portion 212 may be in a range of 100 Angstroms to 200 Angstroms (Å).

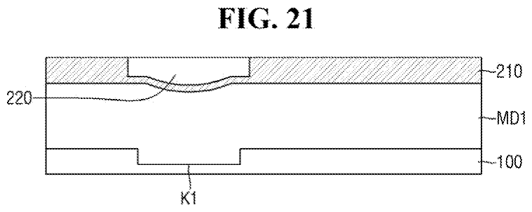

Referring to FIG. 21, the transparent layer 220 may be on the first mask layer 210. The transparent layer 220 may be in the key-hole (H1 of FIG. 19). The transparent layer 220 may fill the key-hole (H1 in FIG. 19). A lower surface and a side surface of the transparent layer 220 may be surrounded with the first mask layer 210. The transparent layer 220 may not contact the first mold layer MD1. The lower surface of the transparent layer 220 may be spaced apart from the upper surface of the first mold layer MD1. An upper surface of the transparent layer 220 may be coplanar with an upper surface of the first mask layer 210.

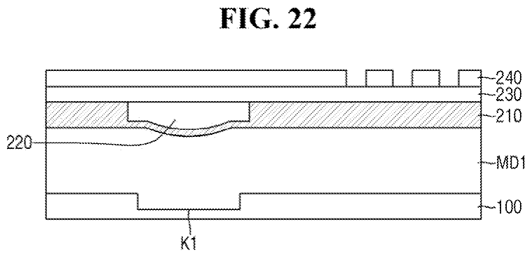

Referring to FIG. 22, the second mask layer 230 and the third mask layer 240 may be on the transparent layer 220 and the first mask layer 210. The third mask layer 240 may be aligned using the first step key K1. It may be determined using the first step key K1 whether the pattern of the third mask layer 240 for etching the first mold layer MD1 overlies on a target position.

To determine whether the third mask layer 240 is aligned correctly, light may be irradiated on the first step key K1. The light transmittance of the first mask layer 210 may be smaller than that of the transparent layer 220. However, a thickness of the first mask layer 210 under the transparent layer 220 may be small such that light can be stably irradiated to the first step key K1. In an implementation, the thickness (TH212 of FIG. 20) of the second portion of the first mask layer 210 under the transparent layer 220 may be 200 angstroms or smaller.

Whether the third mask layer 240 is aligned correctly may be determined based on a result of detecting a polarization state and diffraction of light irradiated to the first step key K1 through the transparent layer 220 and the first mask layer 210.

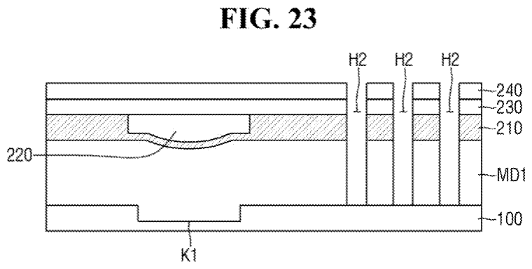

Referring to FIG. 23, the pattern hole H2 may be formed using the third mask layer 240. Using the pattern of the third mask layer 240, the first mold layer MD1, the first mask layer 210, and the second mask layer 230 may be etched.

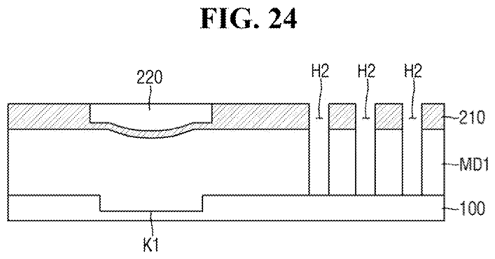

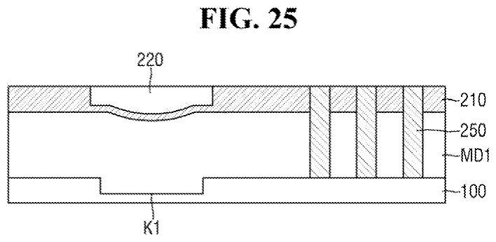

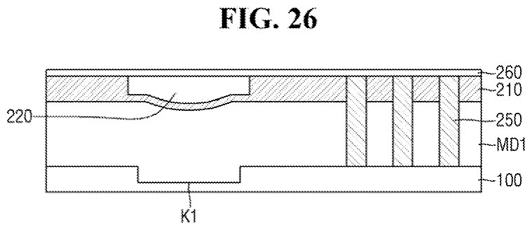

Referring to FIG. 24, the second mask layer 230 and the third mask layer 240 may be removed. Referring to FIG. 25, the pillar structure 250 may be formed. Referring to FIG. 26, the protective film 260 may be formed. The protective film 260 may cover the pillar structure 250, the first mask layer 210, and the transparent layer 220.

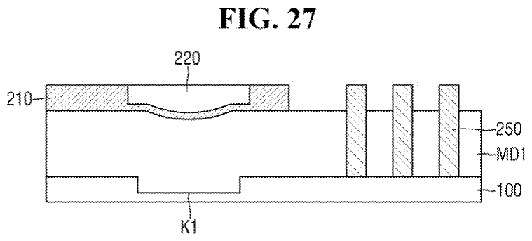

FIG. 27 to FIG. 29 are diagrams showing intermediate structures respectively corresponding to intermediate steps of a method for manufacturing a semiconductor device according to example embodiments. For the convenience of description, differences from those described with reference to FIG. 19 to FIG. 26 will be mainly described. For reference, FIG. 27 is a diagram showing a step subsequent to FIG. 25.

Referring to FIG. 25 and FIG. 27, a portion of the first mask layer 210 may be removed. In an area where the pillar structure 250 is, the first mask layer 210 may be removed. The remaining portion of the first mask layer 210 may surround the transparent layer 220. The first mask layer 210 may surround side and lower surfaces of the transparent layer 220.

The pillar structure 250 may not be surrounded with the first mask layer 210. The pillar structure 250 may protrude upwardly beyond the top face of the first mold layer MD1. The pillar structure 250 may not be in contact with the first mask layer 210.

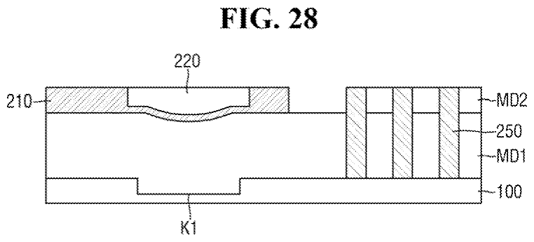

Referring to FIG. 28, the second mold layer MD2 may be formed. The second mold layer MD2 may be between the pillar structures 250. The second mold layer MD2 may be spaced apart from the first mask layer 210. The second mold layer MD2 may not contact the first mask layer 210.

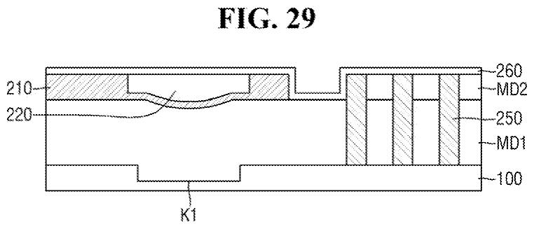

Referring to FIG. 29, the protective film 260 may be formed. The protective film 260 may be on the transparent layer 220, the first mold layer MD1, the first mask layer 210, the pillar structure 250, and the second mold layer MD2. The transparent layer 220 may be surrounded with the first mask layer 210 and the protective film 260.

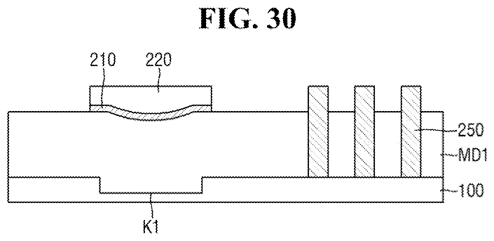

FIG. 30 to FIG. 32 are diagrams showing intermediate structures respectively corresponding to intermediate steps of a method for manufacturing a semiconductor device according to example embodiments. For the convenience of description, differences from those described with reference to FIG. 19 to FIG. 26 will be mainly described. For reference, FIG. 30 is a diagram showing a step subsequent to FIG. 25.

Referring to FIG. 25 and FIG. 30, a portion of the first mask layer 210 may be removed. A portion of the first mask layer 210 that does not overlap with the transparent layer 220 may be removed. The remaining portion of the first mask layer 210 may be under the transparent layer 220. The remaining portion of the first mask layer 210 may be between the transparent layer 220 and the first mold layer MD1. The remaining portion of the first mask layer 210 may overlap with the first step key K1. A sidewall of the remaining portion of the first mask layer 210 may be coplanar with a sidewall of the transparent layer 220. A width of each of the remaining portion of the first mask layer 210 and the transparent layer 220 may be greater than a width of the first step key K1.

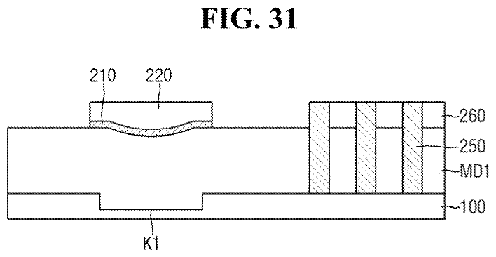

Referring to FIG. 31, the second mold layer MD2 may be formed. The second mold layer MD2 may be between the pillar structures 250. The second mold layer MD2 may be spaced apart from the first mask layer 210 and the transparent layer 220. The second mold layer MD2 may not overlap with the first step key K1.

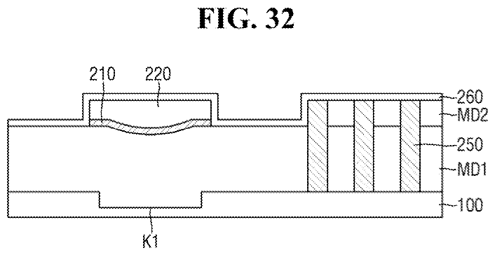

Referring to FIG. 32, the protective film 260 may be formed. The protective film 260 may be on the transparent layer 220, the first mold layer MD1, the first mask layer 210, the pillar structure 250, and the second mold layer MD2. The protective film 260 may cover a sidewall of each of the first mask layer 210 and the transparent layer 220.

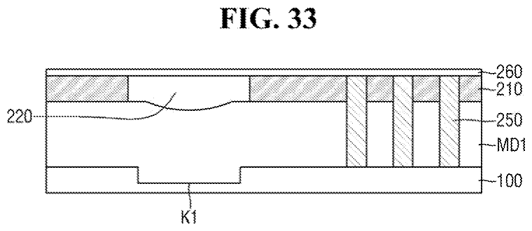

FIG. 33 is a diagram showing intermediate structures respectively corresponding to intermediate steps of a method for manufacturing a semiconductor device according to example embodiments. For the convenience of description, differences from those described with reference to FIG. 1 to FIG. 12 will be mainly described. For reference, FIG. 33 is a diagram showing a step subsequent to FIG. 10.

Referring to FIG. 10 and FIG. 33, the protective film 260 may be on the first mask layer 210. Referring to FIG. 33 in comparison to FIG. 11, while the first mask layer 210 and the transparent layer 220 are not removed, the protective film 260 may be formed. The protective film 260 may be on the transparent layer 220, the first mask layer 210, and the pillar structure 250.

The upper surface of the pillar structure 250 may be covered with the protective film 260. A portion of the side surface of the pillar structure 250 may be surrounded with the first mask layer 210. The first mask layer 210 and the pillar structure 250 may be in direct contact with each other.

A material of the first mask layer 210 and a material of the pillar structure 250 may be different from each other. In an implementation, the first mask layer 210 may include silicon alloy, and the pillar structure 250 may include titanium nitride (TiN). Even though the first mask layer 210 and the pillar structure 250 may be in direct contact with each other, the first mask layer 210 may not affect an electrical operation of the pillar structure 250.

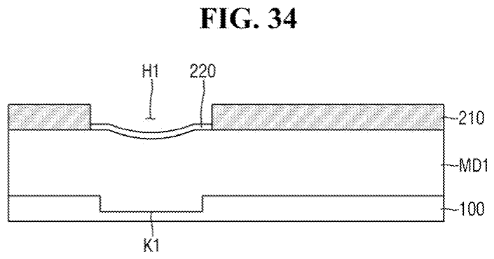

FIG. 34 to FIG. 39 are diagrams showing intermediate structures respectively corresponding to intermediate steps of a method for manufacturing a semiconductor device according to example embodiments. For the convenience of description, differences from those described with reference to FIG. 1 to FIG. 12 will be mainly described. For reference, FIG. 34 is a diagram showing a step subsequent to FIG. 3.

Referring to FIG. 34, the transparent layer 220 may be in the key-hole H1. The transparent layer 220 may be formed in an ASD (area selective deposition) manner. The transparent layer 220 may be on only a surface of the first mold layer MD1. The transparent layer 220 may not be on the first mask layer 210. The transparent layer 220 may not contact the first mask layer 210. An upper surface of the transparent layer 220 in the keyhole H1 may be under an upper surface of the first mask layer 210.

FIG. 34 shows that a sidewall of the transparent layer 220 is in contact with the sidewall of the first mask layer 210. The sidewall of the transparent layer 220 may not contact the sidewall of the first mask layer 210.

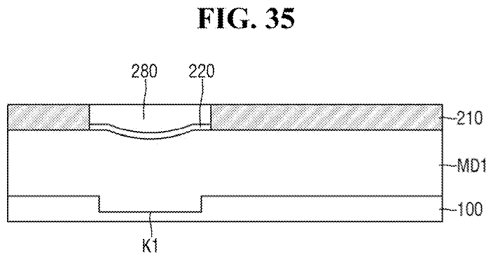

Referring to FIG. 35, a filling film 280 may be on the transparent layer 220. The filling film 280 may fill the key-hole (H1 of FIG. 34). The filling film 280 may cover the transparent layer 220. The filling film 280 may overlap the transparent layer 220. An upper surface of the filling film 280 may be coplanar with an upper surface of the first mask layer 210. A side surface of each of the transparent layer 220 and the filling film 280 may be surrounded with the first mask layer 210.

Light transmittance of the filling film 280 may be greater than that of the first mask layer 210. The light transmittance of the filling film 280 may be lower than that of the transparent layer 220. In an implementation, the filling film 280 may include silicon oxide.

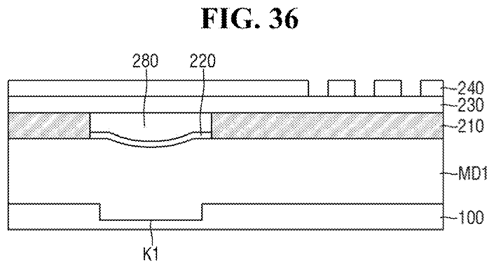

Referring to FIG. 36, the second mask layer 230 and the third mask layer 240 may be on the first mask layer 210 and the filling film 280. The third mask layer 240 may be aligned using the first step key K1. It may be determined using the first step key K1 whether the pattern of the third mask layer 240 for etching the first mold layer MD1 overlies on the target position.

To determine whether the third mask layer 240 is aligned correctly, light may be irradiated to the first step key K1. The light irradiated to the first step key K1 may travel through the filling film 280 and the transparent layer 220and then may reach the first step key K1.

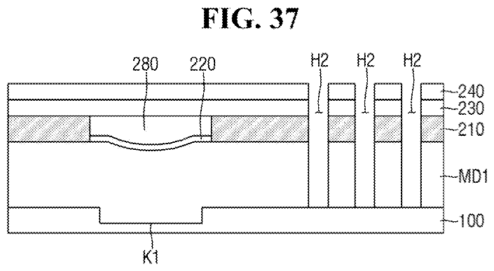

Referring to FIG. 37, the first mold layer MD1 may be etched using the third mask layer 240. The pattern hole H2 may be in the first mold layer MD1, the first mask layer 210, and the second mask layer 230 using the pattern of the third mask layer 240. The pattern hole H2 may extend through the first mold layer MD1 and the first mask layer 210. Using the first step key K1, the pattern hole H2 may be at a target location on the substrate 100.

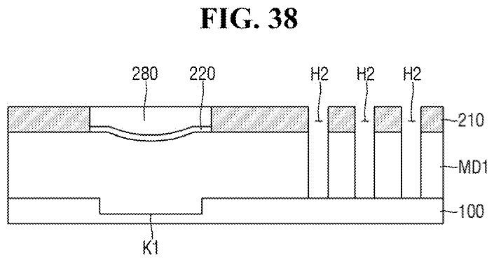

Referring to FIG. 38, the second mask layer 230 and the third mask layer 240 may be removed. The first mask layer 210 and the filling film 280 may be exposed. The pattern hole H2 may be in the first mold layer MD1 and the first mask layer 210.

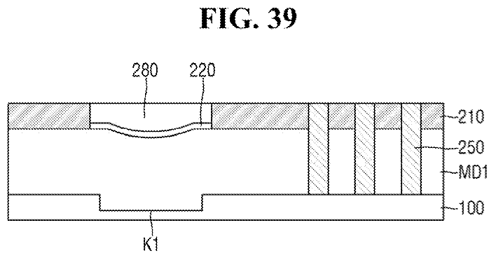

Referring to FIG. 39, the pillar structure 250 may be formed. The pillar structure 250 may be in the pattern hole (H2 in FIG. 38). The pillar structure 250 may fill the pattern hole (H2 in FIG. 38). A pattern material may fill the pattern hole (H2 in FIG. 38). An upper surface of the pillar structure 250 may be coplanar with an upper surface of each of the first mask layer 210 and the filling film 280.

Based on the lower surface of the substrate 100, the upper surface of the pillar structure 250 may be positioned at a higher level than that of the upper surface of the first mold layer MD1. Based on the lower surface of the substrate 100, the upper surface of the pillar structure 250 may be positioned at a higher level than that of the upper surface of the transparent layer 220.

A step after FIG. 39 is substantially the same as that as described with reference to FIGS. 11 and 12, and thus is briefly described. Subsequently, referring to FIG. 39, FIG. 11 and FIG. 12, the first mask layer 210, the filling film 280, and the transparent layer 220 may be removed.

As the first mask layer 210, the filling film 280, and the transparent layer 220 have been removed, the upper surface of the first mold layer MD1 may be exposed. The pillar structure 250 may protrude upwardly beyond the upper surface of the first mold layer MD1.

Subsequently, the second mold layer MD2 and the protective film 260 may be on the first mold layer MD1. The second mold layer MD2 may surround a portion of an exposed sidewall of the pillar structure 250. The protective film 260 may extend along the upper surface of the second mold layer MD2. The protective film 260 may cover the upper surface of the pillar structure 250.

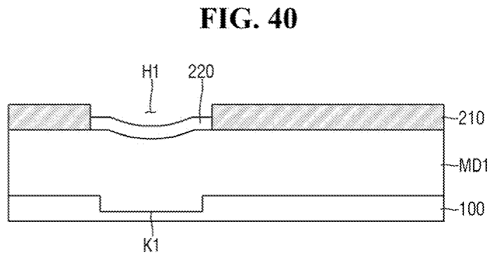

FIG. 40 to FIG. 45 are diagrams showing intermediate structures respectively corresponding to intermediate steps of a method for manufacturing a semiconductor device according to example embodiments. For the convenience of description, differences from those described with reference to FIG. 34 to FIG. 39 will be mainly described. For reference, FIG. 40 is a diagram showing a step subsequent to FIG. 3.

Referring to FIG. 40, the transparent layer 220 may be in the key-hole H1. The transparent layer 220 may be formed in an ASD (area selective deposition) manner. The transparent layer 220 may be on only the surface of the first mold layer MD1. The transparent layer 220 may not be on the first mask layer 210. The transparent layer 220 may not contact the first mask layer 210. An upper surface of the transparent layer 220 in the keyhole H1 may be under an upper surface of the first mask layer 210.

Referring to FIG. 40 in comparison to FIG. 34, a thickness of the transparent layer 220 in FIG. 40 may be greater than a thickness of the transparent layer 220 in FIG. 34. A step between the upper surface of the transparent layer 220 and the upper surface of the first mask layer 210 in FIG. 40 may be smaller than a step between the upper surface of the transparent layer 220 and the upper surface of the first mask layer 210 in FIG. 23.

FIG. 40 shows that the sidewall of the transparent layer 220 contacts the sidewall of the first mask layer 210. The sidewall of the transparent layer 220 may not contact the sidewall of the first mask layer 210.

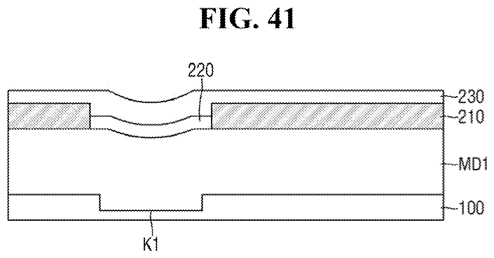

Referring to FIG. 41, the second mask layer 230 may be on the first mask layer 210 and the transparent layer 220. The second mask layer 230 may fill the key-hole (H1 in FIG. 40). The second mask layer 230 may be on the transparent layer 220 in the key-hole (H1 in FIG. 40). The second mask layer 230 may cover the first mask layer 210 and the transparent layer 220. The second mask layer 230 may have a curved surface in an area overlapping the first step key K1.

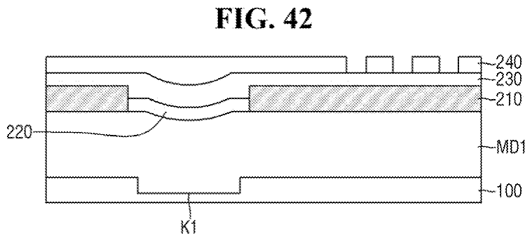

Referring to FIG. 42, the third mask layer 240 may be on the second mask layer 230. The third mask layer 240 may cover the second mask layer 230. The third mask layer 240 may be aligned using the first step key K1. It may be determined using the first step key K1 whether the pattern of the third mask layer 240 for etching the first mold layer MD1 overlies on the target position.

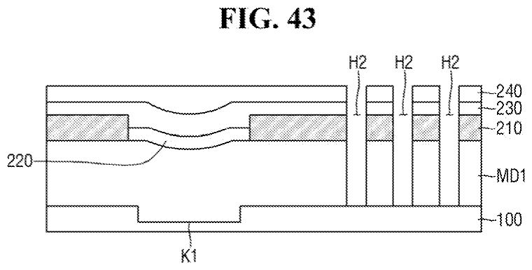

Referring to FIG. 43, the first mold layer MD1 may be etched using the third mask layer 240. The pattern hole H2 may be in the first mold layer MD1, the first mask layer 210, and the second mask layer 230 using the pattern of the third mask layer 240. The pattern hole H2 may extend through the first mold layer MD1 and the first mask layer 210. Using the first step key K1, the pattern hole H2 may be at a target location on the substrate 100.

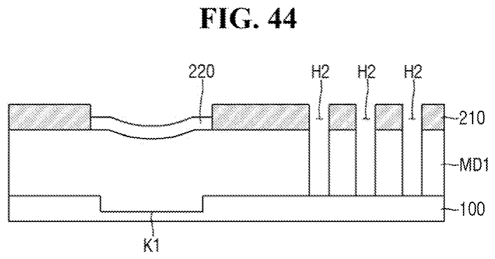

Referring to FIG. 44, the second mask layer 230 and the third mask layer 240 may be removed. The first mask layer 210 and the transparent layer 220 may be exposed. Based on the lower surface of the substrate 100, the upper surface of the transparent layer 220 may be under the upper surface of the first mask layer 210. The pattern hole H2 may be in the first mold layer MD1 and the first mask layer 210.

The transparent layer 220 may have an etch selectivity with respect to each of the second mask layer 230 and the third mask layer 240. Therefore, the second mask layer 230 and the third mask layer 240 may be removed, while the transparent layer 220 may not be removed.

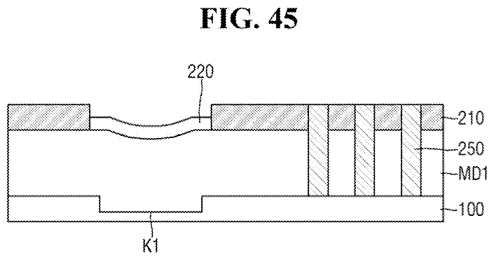

Referring to FIG. 45, the pillar structure 250 may be formed. The pillar structure 250 may be in the pattern hole (H2 in FIG. 38). The pillar structure 250 may fill the pattern hole (H2 in FIG. 38). The upper surface of the pillar structure 250 may be coplanar with the upper surface of the first mask layer 210. Based on the lower surface of the substrate 100, the upper surface of the pillar structure 250 may be positioned at a higher level than that of the upper surface of the transparent layer 220.

A step after FIG. 45 is substantially the same as that as described with reference to FIGS. 11 and 12, and thus is briefly described. Subsequently, referring to FIG. 45, FIG. 11 and FIG. 12, the first mask layer 210 and the transparent layer 220 may be removed. Subsequently, the second mold layer MD2 and the protective film 260 may be on the first mold layer MD1. The second mold layer MD2 may surround a portion of the sidewall of the pillar structure 250 as exposed when the first mask layer 210 is removed. The protective film 260 may extend along the upper surface of the second mold layer MD2. The protective film 260 may cover the upper surface of the pillar structure 250.

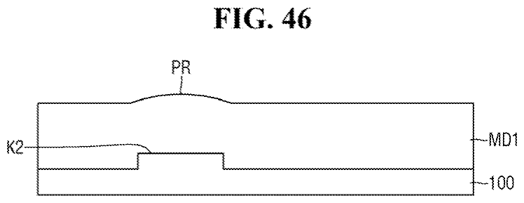

FIG. 46 to FIG. 54 are diagrams showing intermediate structures respectively corresponding to intermediate steps of a method for manufacturing a semiconductor device according to example embodiments. For the convenience of description, differences from those described with reference to FIG. 1 to FIG. 12 will be mainly described.

Referring to FIG. 46, a second step key K2 and the first mold layer MD1 may be on the substrate 100. The second step key K2 may include a convex protrusion toward the first mold layer MD1. In an implementation, the second step key K2 may have a step protruding upwardly from the upper surface of the substrate 100.

The first mold layer MD1 may be on the substrate 100. The first mold layer MD1 may be on the second step key K2 including the protrusion. The first mold layer MD1 may cover the second step key K2. The first mold layer MD1 is illustrated as being a single layer. In an implementation, the first mold layer MD1 may include a plurality of films.

The first mold layer MD1 may have a curved surface in an area overlapping with the second step key K2. In an implementation, the first mold layer MD1 may have a protrusion PR overlapping with the second step key K2. As the second step key K2 has a convex step toward the first mold layer MD1, the upper surface of the first mold layer MD1 may protrude in a direction opposite to a direction toward the substrate 100 in the area overlapping the second step key K2.

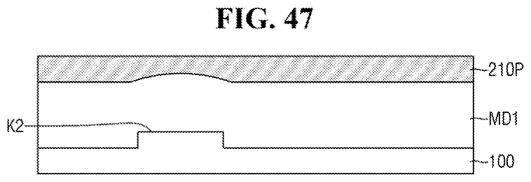

Referring to FIG. 47, the first pre-mask layer 210P may be on the first mold layer MD1. The first pre-mask layer 210P may include a metal material. In an implementation, the first pre-mask layer 210P may include a material doped with metal. The first pre-mask layer 210P may be opaque. Light transmittance of the first pre-mask layer 210P may be lower than that of the first mold layer MD1.

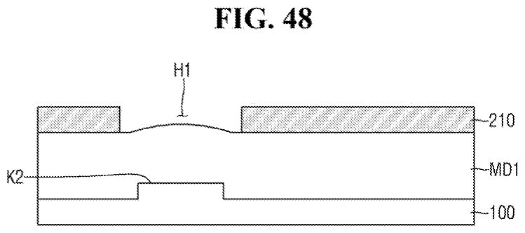

Referring to FIG. 48, the key-hole H1 may be in the first mask layer 210. The key-hole H1 may extend through the first mask layer 210. The key-hole H1 may overlap the second step key K2. The key-hole H1 may expose the upper surface of the first mold layer MD1. The key-hole H1 may expose the curved surface of the first mold layer MD1. The key-hole H1 may expose the protrusion (PR in FIG. 46) of the first mold layer MD1.

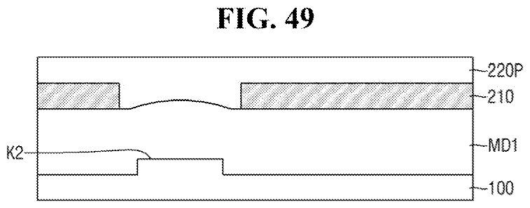

Referring to FIG. 49, the pre-transparent layer 220P may be on the first mask layer 210. Light transmittance of the pre-transparent layer 220P may be greater than light transmittance of the first mask layer 210. The extinction coefficient and the refractive index of the pre-transparent layer 220P may be lower than the extinction coefficient and the refractive index of the first mask layer 210, respectively.

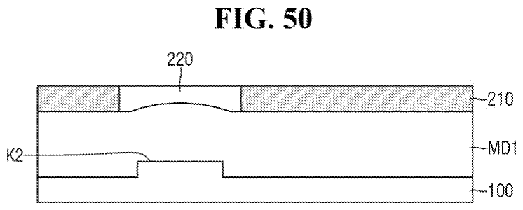

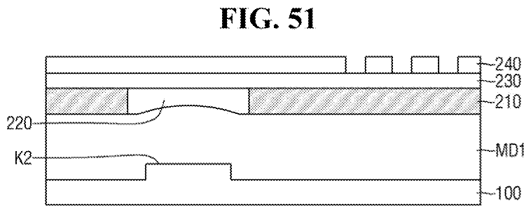

Referring to FIG. 50, the transparent layer 220 may be in the first mask layer 210. Referring to FIG. 51, the second mask layer 230 and the third mask layer 240 may be on the first mask layer 210 and the transparent layer 220.

The third mask layer 240 may include photoresist. The third mask layer 240 may include a pattern for etching the first mold layer MD1. The third mask layer 240 may be aligned using the second step key K2. It may be determined using the second step key K2 whether the pattern of the third mask layer 240 for etching the first mold layer MD1 overlies on the target position.

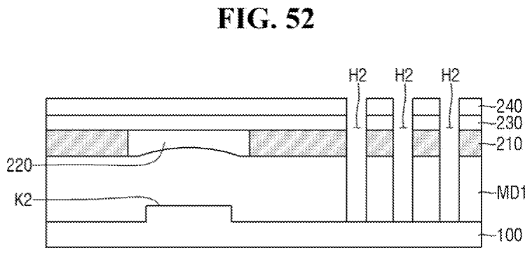

Referring to FIG. 52, the first mold layer MD1 may be etched using the third mask layer 240. The pattern hole H2 may be in the first mask layer 210, the first mold layer MD1, the second mask layer 230, and the third mask layer 240.

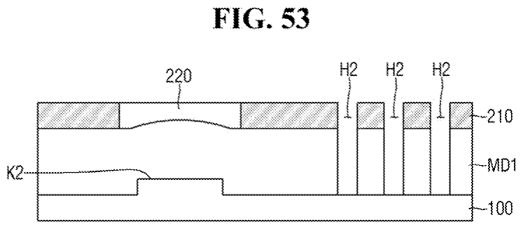

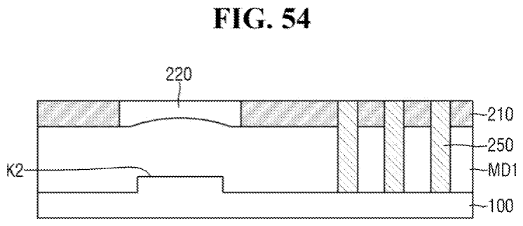

Referring to FIG. 53, the second mask layer 230 and the third mask layer 240 may be removed. Referring to FIG. 54, the pillar structure 250 may be formed.

The upper surface of the pillar structure 250 may be coplanar with the upper surface of the first mask layer 210. Based on the lower surface of the substrate 100, the upper surface of the pillar structure 250 may be positioned at a higher level than that of the upper surface of the first mold layer MD1.

In an implementation, the pillar structure 250 may include a lower electrode of the DRAM capacitor. In another example, the pillar structure 250 may include a channel structure of the non-volatile memory such as NAND. In still another example, the pillar structure 250 may include a through-via of a semiconductor device.

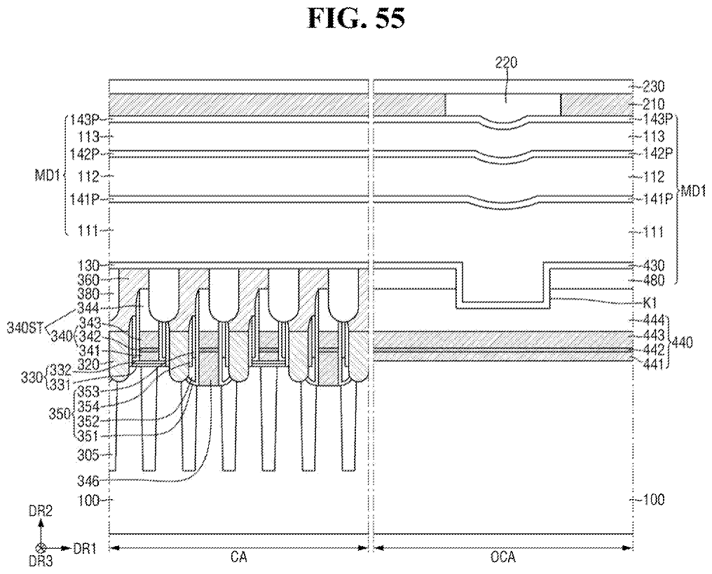

FIG. 55 to FIG. 64 are diagrams showing a semiconductor device manufactured using a method for manufacturing a semiconductor device according to example embodiments. For the convenience of description, differences from those described with reference to FIG. 1 to FIG. 12 will be mainly described.

Referring to FIG. 55, the substrate 100 including a chip area CA and an out-of-chip area OCA may be formed. A plurality of bit-line structures 340ST, a buried contact 320, a landing pad 360, and an etch stop film 130 may be on the substrate 100 and in the chip area CA.

An out-of-chip conductive line 440, an interlayer insulating film 480, and an out-of-chip etch stop film 430 may be on the substrate 100 and in the out-of-chip area OCA. The etch stop film 130 and the out-of-chip etch stop film 430 may be at the same level.

The first step key K1 may be on the substrate 100 and in the out-of-chip area OCA. The first step key K1 may include a trench recessed towards the lower surface of the substrate 100. In an implementation, the first step key K1 may have a step downwardly toward the upper surface of the substrate 100.

The first mold layer MD1 may be across the chip area CA and the out-of-chip area OCA. Subsequently, the first mask layer 210, the transparent layer 220, and the second mask layer 230 may be on the first mold layer MD1.

The first mold layer MD1 may include a first mold film 111, a first pre-supporter film 141p, a second mold film 112, a second pre-supporter film 142p, a third mold film 113 and a third pre-supporter film 143P. The first mold layer MD1 may correspond to the first mold layer MD1 of FIG. 1 to FIG. 54.

In an implementation, each of the first mold film 111, the second mold film 112, and the third mold film 113 may include silicon oxide. Each of the first pre-supporter film 141p, the second pre-supporter film 142p, and the third pre-supporter film 143P may include silicon nitride. Each of the first pre-supporter film 141p, the second pre-supporter film 142p, and the third pre-supporter film 143P may include silicon nitride (SiN), silicon carbonitride (SiCN), silicon oxynitride (SiON), or silicon oxycarbonitride (SiOCN).

In the out-of-chip area OCA, the first mold layer MD1 may be on the first step key K1. The first mold layer MD1 may cover the first step key K1. The first mold layer MD1 may have a curved surface in an area overlapping the first step key K1.

The first mask layer 210 may surround the transparent layer 220. The upper surface of the first mask layer 210 may be coplanar with the upper surface of the transparent layer 220.

The first mask layer 210 may include a metal material. In an implementation, the first mask layer 210 may include a material doped with metal. In some embodiments, the first mask layer 210 may include aluminum (Al), titanium (Ti), chromium (Cr), nickel (Ni), copper (Cu), zirconium (Zr), molybdenum (Mo), ruthenium (Ru), hafnium (Hf), tantalum (Ta), tungsten (W), platinum (Pt), lanthanum (La) or an alloy of the above materials. The first mask layer 210 may be opaque.

The first mask layer 210 may have a higher etch selectivity with respect to that of the first mold layer MD1. The transparent layer 220 may overlap the first step key K1. The width of the transparent layer 220 may be greater than the width of the first step key K1. The transparent layer 220 may be in the first mask layer 210.

The transparent layer 220 may include hafnium oxide (HfO₂), titanium oxide (TiO₂), tantalum oxide (TaO₂), silicon oxide (SiO₂) or silicon nitride (Si₃N₄). The light transmittance of the transparent layer 220 may be greater than that of the first mask layer 210. An extinction coefficient and a refractive index of the transparent layer 220 may be smaller than an extinction coefficient and a refractive index of the first mask layer 210, respectively.

Across the chip area CA and the out-of-chip area OCA, the second mask layer 230 may extend along the first mask layer 210 and the transparent layer 220. The second mask layer 230 may cover the first mask layer 210 and the transparent layer 220.

An element isolation film 305 may be in the substrate 100. The element isolation film 305 may have an STI (shallow trench isolation) structure having excellent element isolation characteristics. The element isolation film 305 may define an active area on the substrate 100.

The active area defined by the element isolation film 305 may have an elongate island shape including a short axis and a long axis. The active area may have an oblique shape to have an angle of smaller than 90 degrees with respect to a word-line in the element isolation film 305.

Each of the element isolation films 305 may include, e.g., a silicon oxide film, a silicon nitride film, or a silicon oxynitride film. Each element isolation film 305 is illustrated as being embodied as one insulating film. Depending on a width of the element isolation film 305, each element isolation film 305 may be composed of one insulating film or a plurality of insulating films.

Further, the active area may have a diagonal shape to have an angle smaller than 90 degrees with respect to the bit-line on the element isolation film 305. The bit-line structure 340ST may include a cell conductive line 340 and a cell line capping film 344. The cell conductive line 340 may be on an area of the substrate 100 in which a gate structure may be formed, and on the element isolation film 305. The cell conductive line 340 may intersect the element isolation film 305 and the active area. The cell conductive line 340 may intersect the gate structure. In this regard, the cell conductive line 340 may correspond to the bit-line.

The cell conductive line 340 may be composed of a stack of multiple-films. The cell conductive line 340 may include, e.g., a first cell conductive film 341, a second cell conductive film 342, and a third cell conductive film 343. The first to third cell conductive films 341, 342, and 343 may be sequentially stacked on the substrate 100 and the element isolation film 305. The cell conductive line 340 is illustrated as being embodied as a stack of triple films.

Each of the first to third cell conductive films 341, 342, and 343 may include, e.g., a semiconductor material doped with impurities, a conductive silicide compound, a conductive metal nitride metal, or a metal alloy. In an implementation, the first cell conductive film 341 may include a doped semiconductor material, the second cell conductive film 342 may include a conductive silicide compound or a conductive metal nitride, and the third cell conductive film 343 may include a metal or a metal alloy. A bit-line contact 346 may be between the cell conductive line 340 and the substrate 100. In an implementation, the cell conductive line 340 may be on the bit-line contact 346. In an implementation, the bit-line contact 346 may be at a point where the cell conductive line 340 intersects a central portion of the active area having the elongate island shape.

The bit-line contact 346 may electrically connect the cell conductive line 340 and the substrate 100 to each other. The bit-line contact 346 may include, e.g., a semiconductor material doped with impurities, a conductive silicide compound, a conductive metal nitride, or a metal.

In an area overlapping an upper surface of the bit-line contact 346, the cell conductive line 340 may include the second cell conductive film 342 and the third cell conductive film 343. In an area that does not overlap with the upper surface of the bit-line contact 346, the cell conductive line 340 may include the first to third cell conductive films 341, 342, and 343.

The cell line capping film 344 may be on the cell conductive line 340. The cell line capping film 344 may extend along the upper surface of the cell conductive line 340. In this regard, the cell line capping film 344 may include, e.g., silicon nitride, silicon oxynitride, silicon carbonitride, or silicon oxycarbonitride. In a semiconductor memory device according to some embodiments, the cell line capping film 344 may include, e.g., a silicon nitride film. The cell line capping film 344 is shown as a single film. The cell line capping film 344 may be composed of a stack of multiple-films. However, when the films constituting the stack of the multiple-films are made of the same material, the cell line capping film 344 may be interpreted as being composed of a single film.

A cell insulating film 330 may be on the substrate 100 and the element isolation film 305. More specifically, the cell insulating film 330 may be on an area of the substrate 100 in which the bit-line contact 346 may not be formed, and on the element isolation film 305. The cell insulating film 330 may be between the substrate 100 and the cell conductive line 340 and between the element isolation film 305 and the cell conductive line 340.

The cell insulating film 330 may be a single film. However, as shown, the cell insulating film 330 may be composed of a stack of multiple-films including a first cell insulating film 331 and a second cell insulating film 332. In an implementation, the first cell insulating film 331 may include a silicon oxide film, and the second cell insulating film 332 may include a silicon nitride film.

A cell line spacer 350 may be on a sidewall of each of the cell conductive line 340 and the cell line capping film 344. The cell line spacer 350 may be on the substrate 100 and the element isolation film 305 in an area of the cell conductive line 340 where the bit-line contact 346 is formed. The cell line spacer 350 may be on a sidewall of each of the cell conductive line 340, the cell line capping film 344 and the bit-line contact 346.

However, in the remaining area of the cell conductive line 340 where the bit-line contact 346 is not formed, the cell line spacer 350 may be on the cell insulating film 330. The cell line spacer 350 may be on a sidewall of each of the cell conductive line 340 and the cell line capping film 344.

The cell line spacer 350 may be a single film. However, as shown, the cell line spacer 350 may be embodied as a stack of multiple films including first to fourth cell line spacers 351, 352, 353, and 354. In an implementation, each of the first to fourth cell line spacers 351, 352, 353, and 354 may include one of a silicon oxide film, a silicon nitride film, a silicon oxynitride film (SiON), a silicon oxycarbonitride film (SiOCN), or air.

In an implementation, the second cell line spacer 352 may not be on the cell insulating film 330 but may be on a sidewall of the bit-line contact 346. While being on an upper surface of the gate structure, the fourth cell line spacer 354 may extend along a sidewall of the cell conductive line 340 adjacent thereto and an upper surface of a gate capping pattern. In an implementation, the second cell line spacer 352 may not be on the cell insulating film 330 but may be on the sidewall of the bit-line contact 346.

The buried contact 320 may be between adjacent bit-lines. In an implementation, the buried contact 320 may be between cell conductive lines 340 adjacent to each other in a first direction DR1. The buried contact 320 may overlap an area of the substrate 100 between adjacent cell conductive lines 340, and the element isolation film 305. The buried contact 320 may be connected to the active area.

The buried contact 320 may include, e.g., a semiconductor material doped with impurities, a conductive silicide compound, a conductive metal nitride, or a metal.

The landing pad 360 may be on the buried contact 320. The landing pad 360 may be electrically connected to the buried contact 320. The landing pad 360 may be connected to a cell active area.

The landing pad 360 may overlap a portion of an upper surface of the bit-line structure 340ST. The landing pad 360 may include, e.g., a semiconductor material doped with impurities, a conductive silicide compound, a conductive metal nitride, a conductive metal carbide, a metal, or a metal alloy.

A pad isolation insulating pattern 380 may be on the landing pad 360 and the bit-line structure 340ST. In an implementation, the pad isolation insulating pattern 380 may be on the cell line capping film 344. The pad isolation insulating pattern 380 may define the landing pad 360 as each of a plurality of isolated areas.

The pad isolation insulating pattern 380 may include an insulating material. The pad isolation insulating pattern 380 may electrically insulate the plurality of landing pads 360 from each other. In an implementation, the pad isolation insulating pattern 380 may include, e.g., a silicon oxide film, a silicon nitride film, a silicon oxynitride film, a silicon oxycarbonitride film, or a silicon carbonitride film.

The out-of-chip conductive line 440 may be at the same level as that of the cell conductive line 340. As used herein, “being at the same level” means being formed in the same manufacturing process. In an implementation, a stack structure of a peripheral common electrode 440 may be the same as a stack structure of the cell conductive line 340.

In an implementation, the out-of-chip conductive line 440 may include a first electrode 441, a second electrode 442, a third electrode 443, and an out-of-chip line capping film 444. The first electrode 441, the second electrode 442, the third electrode 443, and the out-of-chip line capping film 444 may be sequentially stacked in a second direction DR2. The first electrode 441 may be at the same level as that of the first cell conductive film 341. The second electrode 442 may be at the same level as that of the second cell conductive film 342. The third electrode 443 may be at the same level as that of the third cell conductive film 343. The out-of-chip line capping film 444 may be at the same level as that of the cell line capping film 344.

A vertical level of the first electrode 441 in the second direction DR2 may be the same as a vertical level of the first cell conductive film 341 in the second direction DR2. A vertical level of the second electrode 442 in the second direction DR2 may be the same as a vertical level of the second cell conductive film 342 in the second direction D2. A vertical level of the third electrode 443 in the second direction DR2 may be the same as a vertical level of the third cell conductive film 343 in the second direction DR2. A vertical level of the outer line capping film 444 in the second direction DR2 may be the same as a vertical level of the cell line capping film 344 in the second direction DR2.

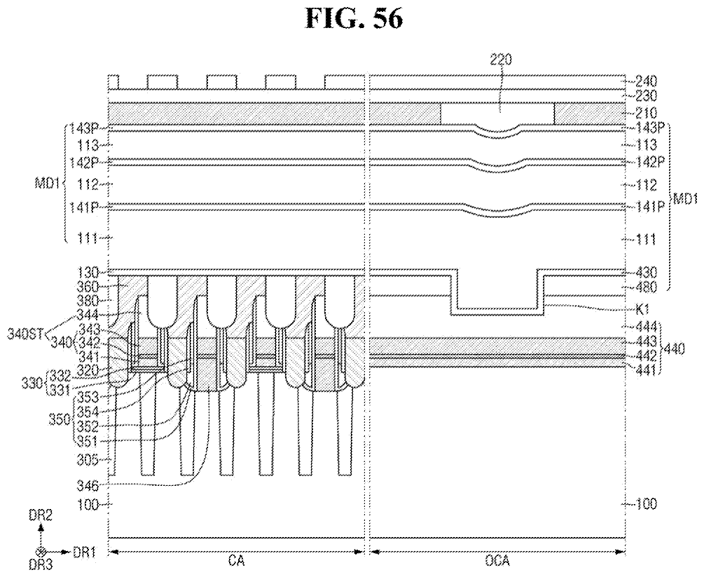

The interlayer insulating film 480 may be at the same level as that of the pad isolation insulating pattern 380. Referring to FIG. 56, the third mask layer 240 may be placed across the chip area CA and the out-of-chip area OCA.

The third mask layer 240 may cover the second mask layer 230. The third mask layer 240 may include photoresist. The third mask layer 240 may include a pattern for etching the first mold layer MD1 in the chip area CA. The pattern of the third mask layer 240 may expose a portion of an upper surface of the second mask layer 230 in the chip area CA.

The third mask layer 240 may be aligned using the first step key K1. It may be determined using the first step key K1 whether the pattern of the third mask layer 240 for etching the first mold layer MD1 overlies on the target position.

Whether the third mask layer 240 is aligned correctly may be determined based on a result of detecting the polarization state and diffraction of light irradiated to the first step key K1 through the transparent layer 220 overlapping the first step key K1. In an implementation, whether a hole formed by etching the first mold layer MD1 using the third mask layer 240 is connected to the landing pad 360 may be determined using the first step key K1.

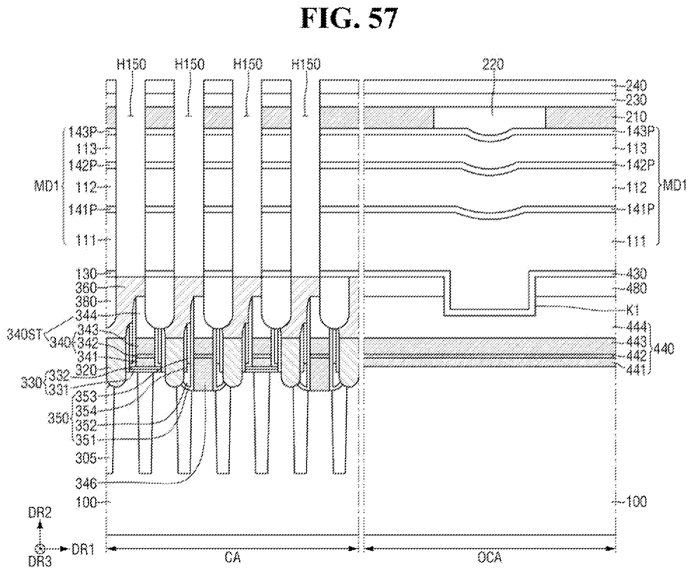

Referring to FIG. 57, the first mold layer MD1 may be etched using the third mask layer 240. A lower electrode hole H150 may be in the first mold layer MD1, the first mask layer 210, and the second mask layer 230 using the pattern of the third mask layer 240. The lower electrode hole H150 may extend through the first mold layer MD1 and the etch stop film 130. The lower electrode hole H150 may expose the landing pad 360.

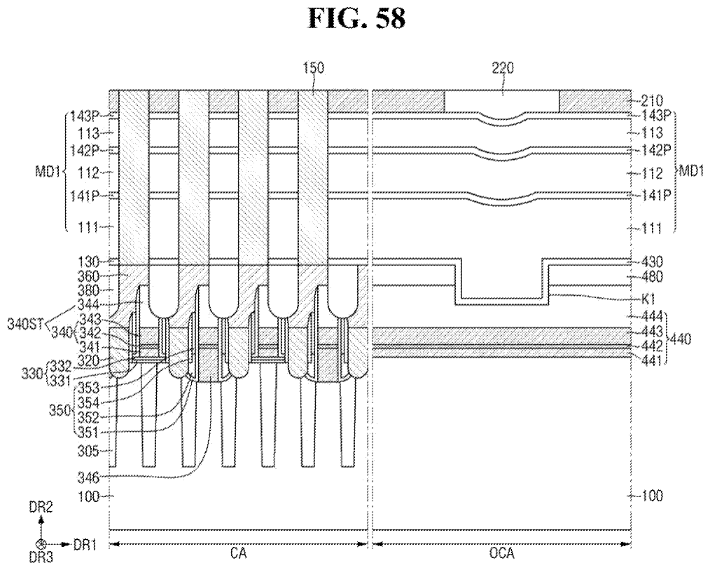

Referring to FIG. 58, the second mask layer 230 and the third mask layer 240 may be removed, and a lower electrode 150 may be formed. The lower electrode 150 may be in the lower electrode hole (H150 in FIG. 57). The lower electrode 150 may fill the lower electrode hole (H150 in FIG. 57). An upper surface of the lower electrode 150 may be coplanar with an upper surface of the first mask layer 210. The lower electrode 150 may be connected to the landing pad 360. The lower electrode 150 may contact the landing pad 360.

The lower electrode 150 may include, e.g., a doped semiconductor material, a conductive metal nitride (such as titanium nitride, tantalum nitride, niobium nitride or tungsten nitride), a metal (such as ruthenium, iridium, titanium or tantalum), or a conductive metal oxide (such as iridium oxide or niobium oxide). In a semiconductor device according to some embodiments, the lower electrode 150 may include titanium nitride (TiN). Further, in a semiconductor device according to some embodiments, the lower electrode 150 may include niobium nitride (NbN).

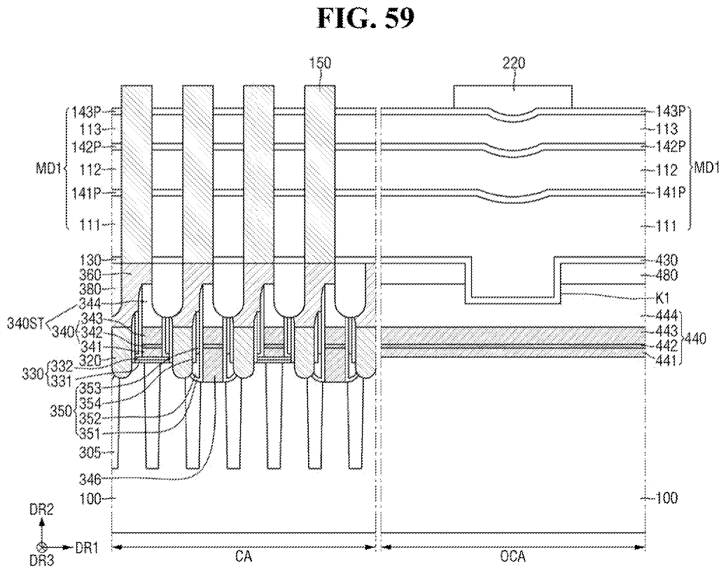

Referring to FIG. 59, the first mask layer 210 may be removed. In the chip area CA and the out-of-chip area OCA, the first mold layer MD1 may be exposed. A portion of each of the third pre-supporter film 143P and the lower electrode 150 may be exposed in the chip area CA. A portion of a sidewall of the lower electrode 150 surrounded with the first mask layer 210 may be exposed. In the out-of-chip area OCA, the third pre-supporter film 143P and the transparent layer 220 may be exposed. The transparent layer 220 may protrude from a top surface of the first mold layer MD1 in the out-of-chip area OCA.

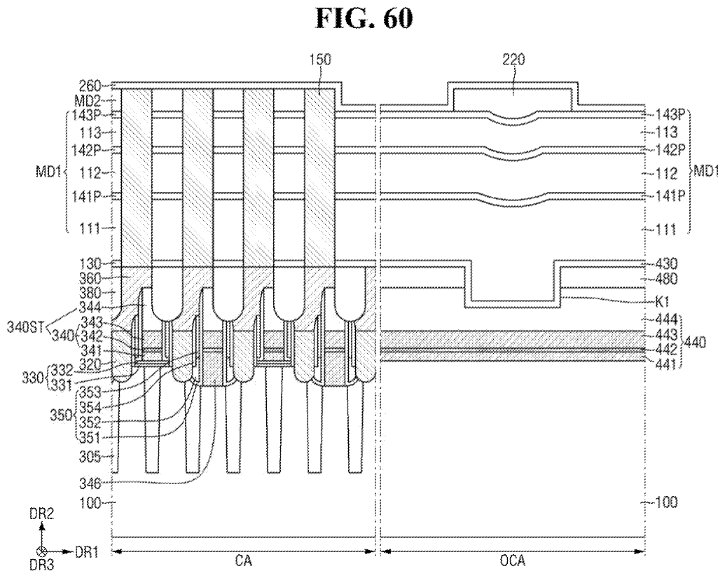

Referring to FIG. 60, the second mold layer MD2 and the protective film 260 may be formed. The second mold layer MD2 may be between the lower electrodes 150 in the chip area CA. The protective film 260 may be across the chip area CA and the out-of-chip area OCA. The protective film 260 may extend along profiles of the second mold layer MD2, the lower electrode 150, and the transparent layer 220.

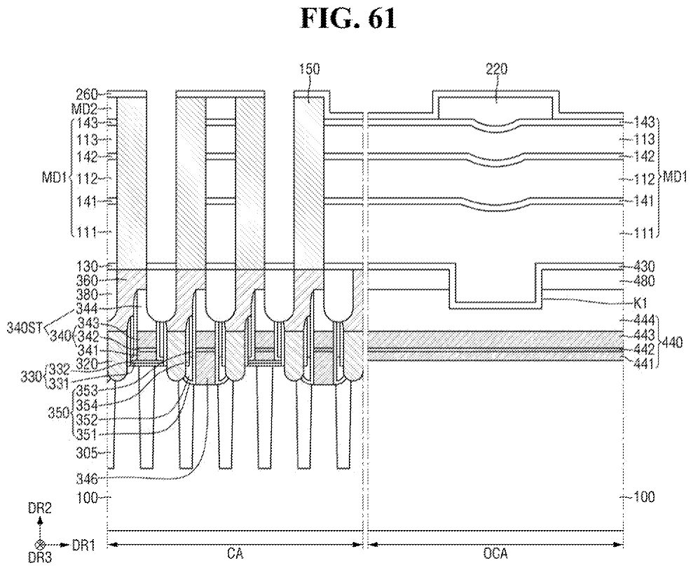

Referring to FIG. 61, the first mold layer MD1 may be patterned. The first mold layer MD1 may be patterned in the chip area CA to form the first supporter film 141, the second supporter film 142, and the third supporter film 143. The first mold film 111, the first pre-supporter film (141p of FIG. 60), the second mold film 112, the second pre-supporter film (142p of FIG. 60), the third mold film 113, and the third pre-supporter film (143P of FIG. 60) may be partially removed. The first supporter film 141, the second supporter film 142, and the third supporter film 143 may connect adjacent lower electrodes 150 to each other. Each of the first supporter film 141, the second supporter film 142, and the third supporter film 143 may contact a portion of the sidewall of the lower electrode 150.

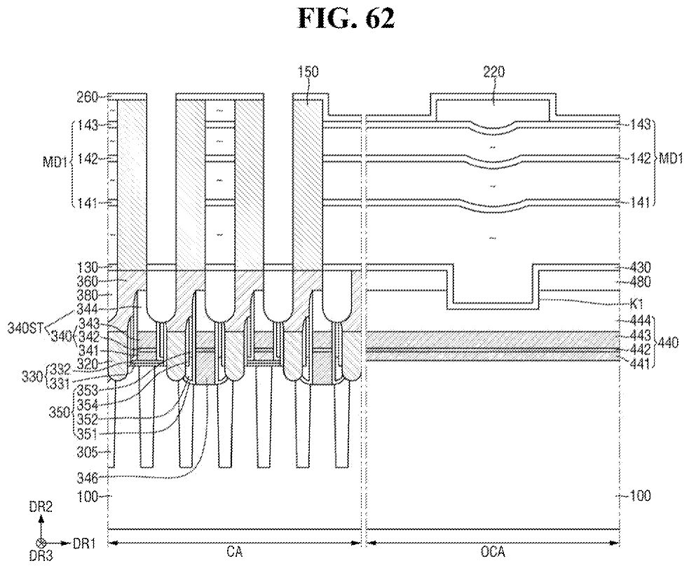

Referring to FIG. 62, the first mold film 111, the second mold film 112, the third mold film 113, and the second mold layer MD2 may be removed. The first mold film 111, the second mold film 112, the third mold film 113 and the second mold layer MD2 may be removed through an area in which each of the first supporter film 141, the second supporter film 142, the third supporter film 143 is not in contact with the lower electrode 150.

The transparent layer 220 may have an etch selectivity with respect to each of the first mold film 111, the second mold film 112, the third mold film 113, and the second mold layer MD2. In an implementation, when each of the first mold film 111, the second mold film 112, the third mold film 113 and the second mold layer MD2 includes silicon oxide, the transparent layer 220 may include hafnium oxide (HfO₂), titanium oxide (TiO₂) or tantalum oxide (TaO₂). Therefore, even when the first mold film 111, the second mold film 112, the third mold film 113, and the second mold layer MD2 are removed, the transparent layer 220 may not be removed.

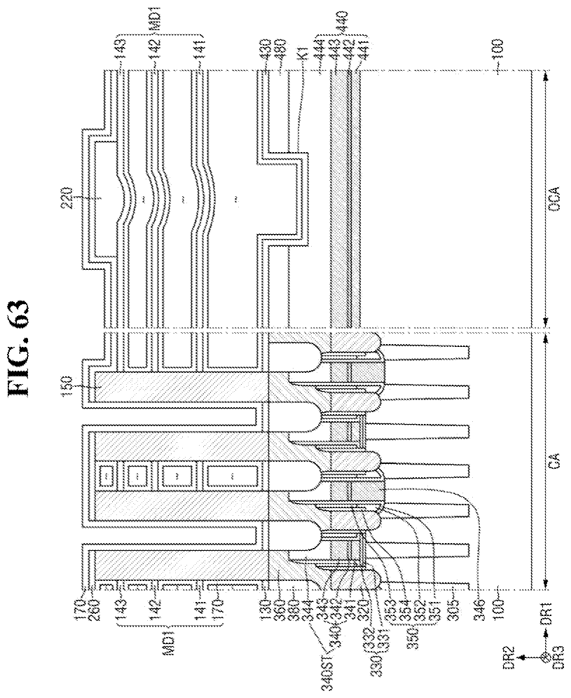

Referring to FIG. 63, a capacitor dielectric film 170 may be formed. The capacitor dielectric film 170 may extend along the etch stop film 130, the first supporter film 141, the second supporter film 142, the third supporter film 143, and the protective film 260. The capacitor dielectric film 170 may extend along the sidewall of the lower electrode 150. The capacitor dielectric film 170 may cover the protective film 260.

The capacitor dielectric film 170 may include one selected from, e.g., silicon oxide, silicon nitride, silicon oxynitride, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The capacitor dielectric film 170 is shown as a single film. In a semiconductor device according to some embodiments, the capacitor dielectric film 170 may have a stack structure of a ferroelectric material film and a paraelectric material film.

The ferroelectric material film may have ferroelectric properties. The ferroelectric material film may have a thickness sized to have ferroelectric properties. A thickness range in which the ferroelectric material film has the ferroelectric properties may vary depending on a type of a ferroelectric material.

In an implementation, the ferroelectric material film may include a monometal oxide. The ferroelectric material film may include a monometal oxide film. In this regard, the monometal oxide may be a binary compound composed of one metal and oxygen. The ferroelectric material film including the monometal oxide may have an orthorhombic crystal system.

In one example, the metal included in the monometal oxide film may be hafnium (Hf). The monometal oxide film may be a hafnium oxide film (HfO). In this regard, the hafnium oxide may have a chemical formula that meets a stoichiometry, or may have a chemical formula that does not meet the stoichiometry.

In another example, the metal included in the monometal oxide film may be one of rare earth metals belonging to the lanthanoids. The monometal oxide film may be made of an oxide of the rare earth metal belonging to the lanthanoids. In this regard, the oxide of the rare earth metal belonging to the lanthanoids may have a chemical formula meeting a stoichiometry or may have a chemical formula which does not meet the stoichiometry.

The ferroelectric material film may further contain a dopant doped in the monometal oxide film. A doping concentration may vary depending on a type of the dopant, the doping concentration of the dopant contained in the ferroelectric material film may be 10% or smaller.

In one example, when the monometal oxide film is the hafnium oxide film, the dopant may include at least one selected from among gadolinium (Gd), silicon (Si), aluminum (Al), yttrium (Y), lanthanum (La), scandium (Sc), cerium (Ce), dysprosium (Dy), tantalum (Ta), strontium (Sr), or niobium (Nb). In another example, when the monometal oxide film is made of the oxide of the rare earth metal belonging to the lanthanoids, the dopant may include silicon (Si), aluminum (Al), hafnium (Hf), zirconium (Zr), or niobium (Nb).

In another example, the ferroelectric material film may not contain the dopant doped in the monometal oxide film. When the ferroelectric material film includes the monometal oxide film, the ferroelectric material film may have a thickness of, e.g., in a range of 1 nm to 10 nm.

In an implementation, the ferroelectric material film may include a bimetal oxide. The ferroelectric material film may include a bimetal oxide film. In this regard, the bimetal oxide may be a ternary compound composed of two metals and oxygen. The ferroelectric material film including the bimetal oxide may have an orthorhombic crystal system.

The metals included in the bimetal oxide film may be, e.g., hafnium (Hf) and zirconium (Zr). The bimetal oxide film may be a hafnium zirconium oxide film (HfₓZr₍₁₋ₓ₎O). In the bimetal oxide film, x may be in a range of 0.2 inclusive to 0.8 inclusive. In this regard, the hafnium zirconium oxide film (HfₓZr₍₁₋ₓ₎O) may have a chemical formula that meets a stoichiometry or may have a chemical formula that does not meet the stoichiometry.

In one example, the ferroelectric material film may further contain a dopant doped into the bimetal oxide film. The dopant may include gadolinium (Gd), silicon (Si), aluminum (Al), yttrium (Y), lanthanum (La), scandium (Sc), cerium (Ce), dysprosium (Dy), tantalum (Ta), or strontium (Sr). In another example, the ferroelectric material film may not contain the dopant doped in the bimetal oxide film. When the ferroelectric material film includes the bimetal oxide film, the ferroelectric material film 132 may have a thickness of, e.g., in a range of 1 nm inclusive to 20 nm inclusive.

In an implementation, the paraelectric material film may be a dielectric film including zirconium (Zr) or a stack film including zirconium (Zr). When a chemical formula of the dielectric material is not changed, the dielectric material may exhibit ferroelectric characteristics or paraelectric characteristics depending on a crystal structure of the dielectric material.

A paraelectric material may have a positive dielectric constant, and a ferroelectric material may have a negative dielectric constant in a certain range. That is, the paraelectric material may have a positive capacitance and the ferroelectric material may have a negative capacitance.

In general, when two or more capacitors having the positive capacitance are connected in series to each other, a total capacitance thereof decreases. However, when a negative capacitor with a negative capacitance and a positive capacitor with a positive capacitance are connected in series to each other, a total capacitance thereof increases.

In FIG. 63, it is shown that the capacitor dielectric film 170 is on the protective film 260. In an implementation, the protective film 260 may be removed before the capacitor dielectric film 170 is formed, and the capacitor dielectric film 170 may be on the lower electrode 150. In this case, the capacitor dielectric film 170 may extend along an upper surface and a sidewall of the lower electrode 150.

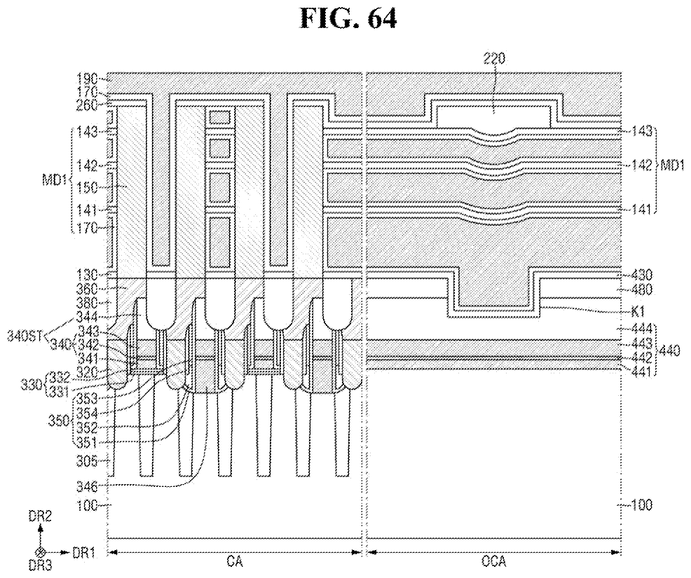

Referring to FIG. 64, an upper electrode 190 may be formed. The upper electrode 190 may be on the lower electrode 150 and the capacitor dielectric film 170. The upper electrode 190 may cover the capacitor dielectric film 170. The upper electrode 190 may cover the transparent layer 220 in the out-of-chip area OCA.

The upper electrode 190 may be made of, e.g., a doped semiconductor material, a conductive metal nitride (such as titanium nitride, tantalum nitride, niobium nitride, or tungsten nitride), a metal (such as ruthenium, iridium, titanium or tantalum), a conductive metal oxide (such as iridium oxide or niobium oxide). In a semiconductor device according to some embodiments, the upper electrode 190 may include titanium nitride (TiN). Alternatively, in a semiconductor device according to some embodiments, the upper electrode 190 may include niobium nitride (NbN).

The semiconductor device according to some embodiments may include a gate structure. The gate structure may be in the substrate 100 and the element isolation film 305. The gate structure may extend across the element isolation film 305 and the active area defined by the element isolation film 305. The gate structure may include a gate trench in the substrate 100 and the element isolation film 305, a gate insulating film, a gate electrode, a gate capping pattern, and a gate capping conductive film. In this regard, the gate electrode may correspond to a word-line. Unlike what is shown, the gate structure may not include the gate capping conductive film.

The gate insulating film may extend along a sidewall and a bottom surface of the gate trench. The gate insulating film may extend along a profile of at least a portion of the gate trench.

The gate insulating film may include, e.g., silicon oxide, silicon nitride, silicon oxynitride, or a high dielectric constant material having a higher dielectric constant than that of silicon oxide. The high dielectric constant material may include, e.g., hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The gate electrode may be on the gate insulating film. The gate electrode may fill a portion of the gate trench. The gate capping conductive film may extend along an upper surface of the gate electrode.

The gate electrode may include a metal, a metal alloy, a conductive metal nitride, a conductive metal carbonitride, a conductive metal carbide, a metal silicide, a doped semiconductor material, a conductive metal oxynitride, or a conductive metal oxide. The gate electrode may include, e.g., TiN, TaC, TaN, TiSiN, TaSiN, TaTiN, TiAlN, TaAlN, WN, Ru, TiAl, TiAlC—N, TiAlC, TiC, TaCN, W, Al, Cu, Co, Ti, Ta, Ni, Pt, Ni—Pt, Nb, NbN, NbC, Mo, MoN, MoC, WC, Rh, Pd, Ir, Ag, Au, Zn, V, RuTiN, TiSi, TaSi, NiSi, CoSi, IrOx, or RuOx. The gate capping conductive film may include, e.g., polysilicon or polysilicon germanium.

The gate capping pattern may be on the gate electrode and the gate capping conductive film. The gate capping pattern may fill a portion of the gate trench remaining after the gate electrode and gate capping conductive film fill a portion of the trench. The gate insulating film is illustrated as extending along a sidewall of the gate capping pattern. The gate capping pattern may include, e.g., silicon nitride (SiN), silicon oxynitride (SiON), silicon oxide (SiO₂), silicon carbonitride (SiCN), or silicon oxycarbonitride (SiOCN). An impurity doped area may be on at least one side of the gate structure. The impurity doped area may be a source/drain area of a transistor.

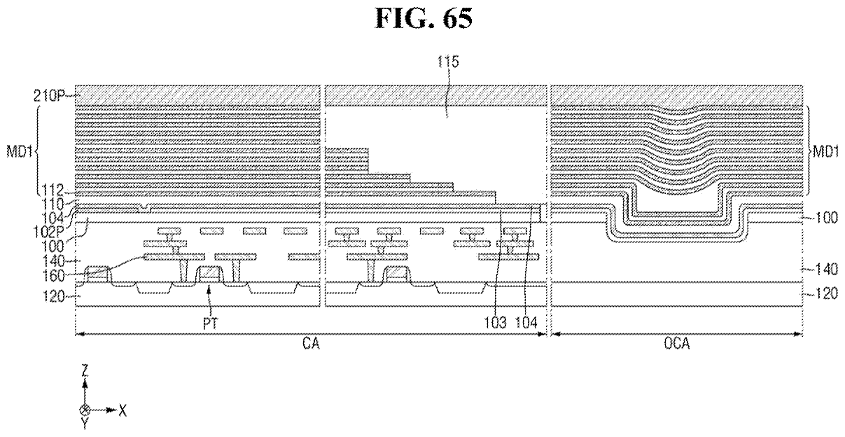

FIG. 65 to FIG. 70 are diagrams showing a semiconductor device manufactured using a method for manufacturing a semiconductor device according to example embodiments. For the convenience of description, differences from those described with reference to FIG. 1 to FIG. 12 will be mainly described. Referring to FIG. 65, a substrate 100 including the chip area CA and the out-of-chip area OCA may be formed.

The first mold layer MD1 and the first pre-mask layer 210P may be formed across the chip area CA and the out-of-chip area OCA. The first mold layer MD1 may include first mold sacrificial films 112 and first mold insulating films 110 that are alternately stacked on top of each other. Each of the first mold sacrificial film 112 and the first mold insulating film 110 in the chip area CA may be at the same level as that of each of the first mold sacrificial film 112 and the first mold insulating film 110 in the out-of-chip area OCA. The first mold layer MD1 may correspond to the first mold layer MD1 of FIG. 1 to FIG. 54.

The first pre-mask layer 210P may include a metal material. In an implementation, the first pre-mask layer 210P may include a material doped with a metal. In some embodiments, the first pre-mask layer 210P may include aluminum (Al), titanium (Ti), chromium (Cr), nickel (Ni), copper (Cu), zirconium (Zr), molybdenum (Mo), ruthenium (Ru), hafnium (Hf), tantalum (Ta), tungsten (W), platinum (Pt), lanthanum (La) or an alloy of the above materials. The first pre-mask layer 210P may be opaque. The first pre-mask layer 210P may have a higher etch selectivity with respect to that of the first mold layer MD1.

In the chip area CA, the first mold layer MD1 may have a stepped structure. A first interlayer insulating film 115 may be on the first mold layer MD1 having the stepped structure in the chip area CA.

The first mold sacrificial film 112 may include a material having an etch selectivity with respect to the first mold insulating film 110. In an implementation, the first mold insulating film 110 may include silicon oxide, and the first mold sacrificial film 112 may include silicon nitride.

In some embodiments, source sacrificial films 102p and 103 and a second source layer 104 may be on the substrate 100 before stacking the first mold sacrificial film 112 and the first mold insulating film 110. The source sacrificial films 102p and 103 may include a material having an etch selectivity with respect to the first mold insulating film 110. In an implementation, the first mold insulating film 110 may include silicon oxide, and the source sacrificial films 102p and 103 may include silicon nitride. The second source layer 104 may include polysilicon doped with impurities or polysilicon free of impurities.

In some embodiments, the substrate 100 may be stacked on a peripheral circuit board 120. In an implementation, a peripheral circuit element PT, a second wiring structure 160 and a second inter-wiring insulating film 140 may be on the peripheral circuit board 120. The substrate 100 may be stacked on the second inter-wiring insulating film 140.

The first step key K1 may be on the substrate 100 and the peripheral circuit board 120 and in the out-of-chip area OCA. The first step key K1 may include a trench recessed toward a lower surface of the peripheral circuit board 120. In an implementation, the first step key K1 may have a step downwardly from the upper surface of the substrate 100.

In the chip area CA, the first pre-mask layer 210P may be on the first mold layer MD1 and the first interlayer insulating film 115. In the out-of-chip area OCA, the first pre-mask layer 210P may be on the first mold layer MD1.

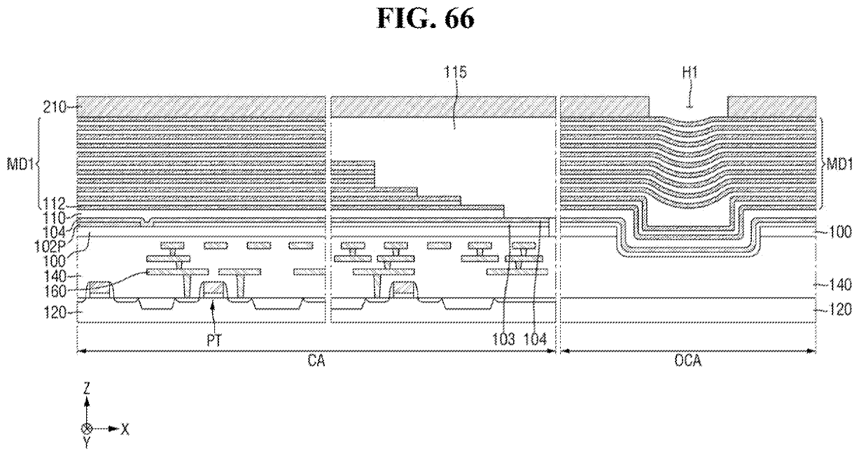

Referring to FIG. 66, the key-hole H1 may be in the first mask layer 210. The key-hole H1 may extend through the first mask layer 210. The key-hole H1 may overlap with the first step key K1. The key-hole H1 may expose an upper surface of the first mold layer MD1. The key-hole H1 may expose a curved surface of the first mold layer MD1.

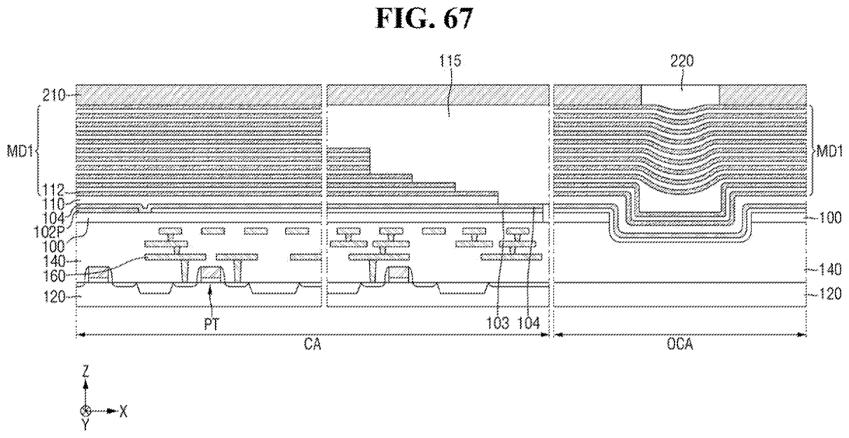

Referring to FIG. 67, the transparent layer 220 may be in the first mask layer 210. An upper surface of the transparent layer 220 may be coplanar with an upper surface of the first mask layer 210. The transparent layer 220 may fill the key-hole (H1 of FIG. 3) in the first mask layer 210. The transparent layer 220 may overlap the first step key K1.

The transparent layer 220 may be surrounded with the first mask layer 210. A sidewall of the transparent layer 220 may be covered with the first mask layer 210. A first width of the transparent layer 220 may be greater than or equal to a second width of the first step key K1.

In FIG. 67, the upper surface of the transparent layer 220 may be coplanar with the upper surface of the first mask layer 210. In an implementation, the upper surface of the transparent layer 220 may be under the upper surface of the first mask layer 210.

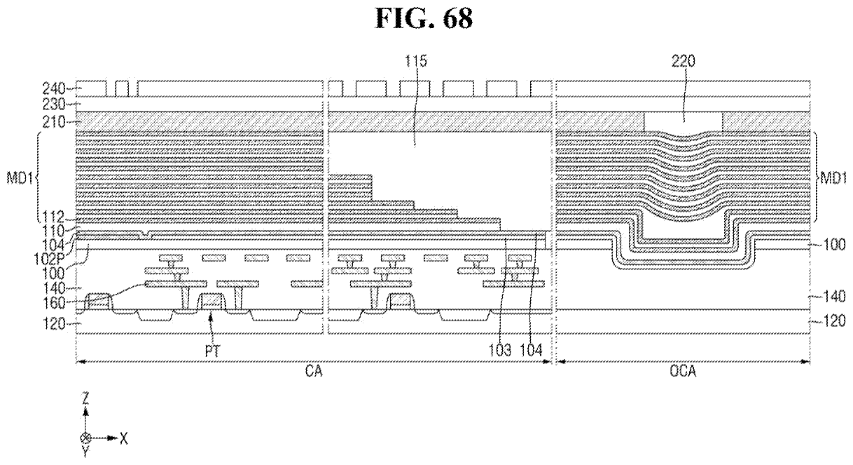

Referring to FIG. 68, the second mask layer 230 and the third mask layer 240 may be across the chip area CA and the out-of-chip area OCA. The third mask layer 240 may cover the second mask layer 230. The third mask layer 240 may include photoresist. The third mask layer 240 may include a pattern for etching the first mold layer MD1 in the chip area CA. The pattern of the third mask layer 240 may expose a portion of the upper surface of the second mask layer 230 in the chip area CA.

The third mask layer 240 may be aligned using the first step key K1. It may be determined using the first step key K1 whether the pattern of the third mask layer 240 for etching the first mold layer MD1 overlies on the target position.

Whether the third mask layer 240 is aligned correctly may be determined based on a result of detecting the polarization state and diffraction of light irradiated to the first step key K1 through the transparent layer 220 overlapping the first step key K1. In an implementation, it may be determined using the first step key K1 whether a channel hole formed by etching the first mold layer MD1 using the third mask layer 240 is disposed at an appropriate position.

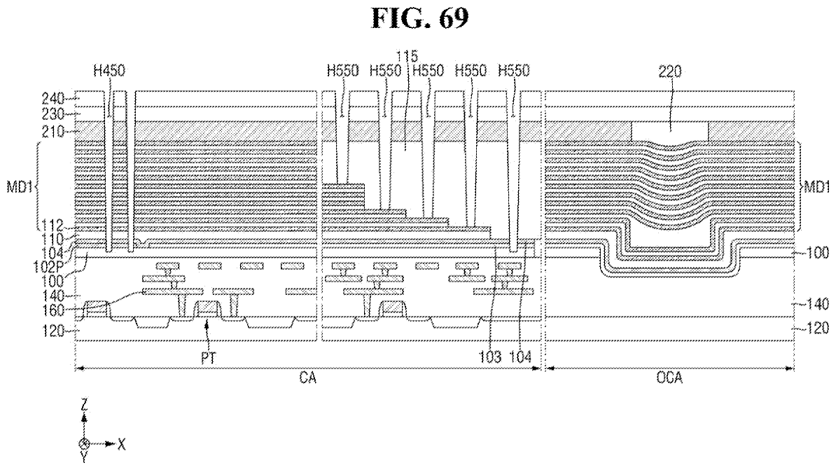

Referring to FIG. 69, the first mold layer MD1 may be etched using the third mask layer 240. A channel hole H450 and a contact hole H550 may be in the first mold layer MD1, the first mask layer 210, and the second mask layer 230 using the pattern of the third mask layer 240.

The channel hole H450 may extend through the first mold layer MD1, the source sacrificial film 102p, and the second source layer 104. The contact hole H550 may extend through the first interlayer insulating film 115, the source sacrificial film 103, and the second source layer 104.

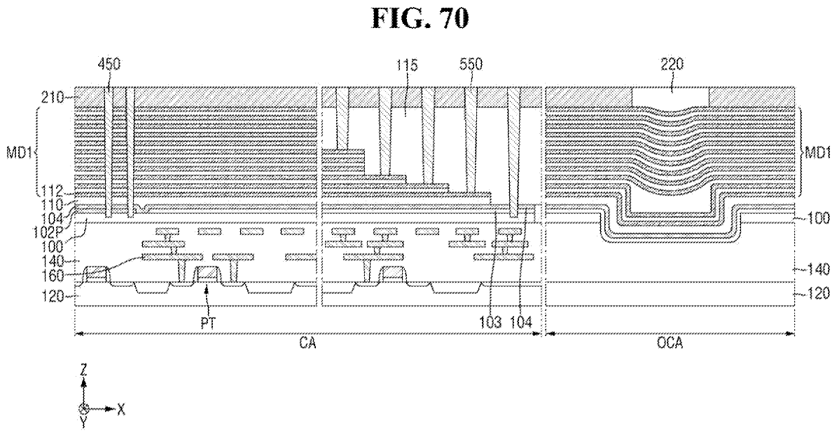

Referring to FIG. 70, the second mask layer 230 and the third mask layer 240 may be removed, and a channel structure 450 and a cell contact 550 may be formed. The channel structure 450 may be in the channel hole (H450 in FIG. 69). The channel structure 450 may fill the channel hole (H450 in FIG. 69). The channel structure 450 may extend through the first mold layer MD1.

The channel structure 450 is shown as be embodied as a single film in FIG. 70. In an implementation, the channel structure 450 may be composed of a stack of multiple-films including a semiconductor pattern and an information storage film.

The semiconductor pattern of the channel structure 450 may extend in a third direction Z through the first mold layer MD2. The semiconductor pattern of the channel structure 450 may have each of various shapes such as a cylindrical shape, a square prism shape, and a solid pillar shape. The semiconductor pattern of the channel structure 450 may include a semiconductor material such as single-crystal silicon, poly-crystal silicon, an organic semiconductor, or carbon nanostructure.

The information storage film of the channel structure 450 may be between the semiconductor pattern and each gate electrode. In an implementation, the information storage film of the channel structure 450 may extend along an outer side surface of the semiconductor pattern. The information storage film of the channel structure 450 may include, e.g., silicon oxide, silicon nitride, silicon oxynitride, or a high-k material having a higher dielectric constant than that of silicon oxide. The high dielectric constant material may include, e.g., aluminum oxide, hafnium oxide, lanthanum oxide, tantalum oxide, titanium oxide, lanthanum hafnium oxide, lanthanum aluminum oxide, or dysprosium scandium oxide.

In some embodiments, the information storage film of the channel structure 450 may be composed of a stack of multiple-films. In an implementation, the information storage film of the channel structure 450 may include a tunnel insulating film, a charge storage film, and a blocking insulating film sequentially stacked on the outer side surface of the semiconductor pattern of the channel structure 450.

The tunnel insulating film of the channel structure 450 may include, e.g., silicon oxide or a high-k material having a higher dielectric constant than that of silicon oxide. The high-k material may include aluminum oxide (Al₂O₃) or hafnium oxide (HfO₂). The charge storage layer of the channel structure 450 may include, e.g., silicon nitride. The blocking insulating film of the channel structure 450 may include, e.g., silicon oxide or a high-k material having a higher dielectric constant than that of silicon oxide. The high-k material may include aluminum oxide (Al₂O₃) or hafnium oxide (HfO₂).

In some embodiments, the channel structure 450 may further include a filling pattern. The filling pattern of the channel structure 450 may fill an inner space defined in a cup-shaped semiconductor pattern. The filling pattern of the channel structure 450 may include an insulating material, e.g., silicon oxide.

The cell contact 550 may be in the contact hole (H550 in FIG. 69). The cell contact 550 may fill the contact hole (H550 in FIG. 69). The cell contact 550 may extend through the first interlayer insulating film 115.

The cell contact 550 may include a conductive material, e.g., a metal such as tungsten (W), cobalt (Co), or nickel (Ni), or a semiconductor material such as silicon.

After a step shown in FIG. 70, the mold sacrificial films 112 may be removed and a plurality of gate electrodes may be formed. Subsequently, the source sacrificial film 102p may be selectively removed, and a source layer filling a space remaining by removing a portion of the source sacrificial film 102p may be formed.

The gate electrodes may include a conductive material, e.g., a metal such as tungsten (W), cobalt (Co), or nickel (Ni), or a semiconductor material such as silicon. The source layer may include a conductive material, e.g., polysilicon doped with impurities or a metal.

By way of summation and review, it is becoming increasingly difficult to recognize a key pattern for overlay measurement due to the introduction of the new materials or the complex manufacturing processes. A technical purpose of the present disclosure is to provide a method for manufacturing a semiconductor device with improved overlay measurement accuracy.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated.

Accordingly, it will be understood by those of skill in the art that various changes in form and details may be made.

1. A method for manufacturing a semiconductor device, the method comprising:
forming a step key on a substrate;
forming a mold layer on the step key covering the step key;
forming a first mask layer on the mold layer,
forming a transparent layer in the first mask layer overlapping the step key;
forming a second mask layer on the first mask layer and the transparent layer;
etching the mold layer using the second mask layer,
wherein the first mask layer includes a metal material.

2. The method as claimed in claim 1, wherein the first mask layer includes:
a first portion surrounding a side surface of the transparent layer, and
a second portion under the transparent layer.

3. The method as claimed in claim 2, wherein a second thickness of the second portion from an upper surface of the mold layer is smaller than a first thickness of the transparent layer.

4. The method as claimed in claim 2, wherein a first thickness of the first portion from an upper surface of the mold layer is greater than a second thickness of the second portion from the upper surface of the mold layer.

5. The method as claimed in claim 1, wherein forming the transparent layer includes:
forming a key-hole extending through the first mask layer and overlapping with the step key, and
forming the transparent layer in the key-hole.

6. The method as claimed in claim 5, wherein a first width of the key-hole is greater than a second width of the step key.

7. The method as claimed in claim 5, wherein:
forming the transparent layer in the key-hole includes forming the transparent layer using chemical vapor deposition, physical vapor deposition, or atomic layer deposition, and
an upper surface of the transparent layer and an upper surface of the first mask layer are coplanar with each other.

8. The method as claimed in claim 5, wherein:
forming the transparent layer in the key-hole includes forming the transparent layer on the mold layer and in the key-hole in an area selective deposition manner, and
the transparent layer is not on a surface of the first mask layer, and
based on a lower surface of the substrate, an upper surface of the transparent layer is positioned under an upper surface of the first mask layer.

9. (canceled)

10. The method as claimed in claim 1, wherein the mold layer includes:
a flat surface area non-overlapping with the step key; and
a curved surface area overlapping with the step key.

11. The method as claimed in claim 1, wherein the mold layer includes:
a first mold layer including silicon nitride; and
a second mold layer including silicon oxide.

12. The method as claimed in claim 1, further comprising:
after etching the mold layer, removing the first mask layer; and
forming a protective film covering the transparent layer.

13. The method as claimed in claim 1, wherein a light transmittance of the transparent layer is greater than a light transmittance of the first mask layer.

14. The method as claimed in claim 1, wherein the transparent layer includes hafnium oxide, titanium oxide, tantalum oxide, silicon oxide, or silicon nitride.

15. A method for manufacturing a semiconductor device, the method comprising:
forming a substrate including a chip area and an out-of-chip area;
forming a step key on the out-of-chip area of the substrate;
forming a mold layer on the substrate covering the step key;
forming a first mask layer on the mold layer,
forming a key-hole in the first mask layer overlapping the step key;
forming a transparent layer in the key-hole;
forming a second mask layer on the first mask layer and the transparent layer while aligning the second mask layer using the step key;
etching the mold layer using the second mask layer to form a pattern hole; and
filling the pattern hole with a pattern material to form a pillar structure.

16. The method as claimed in claim 15, wherein the first mask layer includes a metal material.

17. The method as claimed in claim 15, wherein:
the key-hole extends through the first mask layer, and
a lower surface of the transparent layer is in contact with the mold layer.

18. The method as claimed in claim 15, wherein:
a lower surface of the transparent layer is in contact with the first mask layer, and
the first mask layer includes:
a first portion on a side of the transparent layer; and
a second portion under the transparent layer.

19. The method as claimed in claim 18, wherein a first thickness of the first portion from an upper surface of the mold layer is greater than a second thickness of the second portion from the upper surface of the mold layer.

20. The method as claimed in claim 15, wherein:
forming the pattern hole includes etching the first mask layer and the mold layer,
forming the pillar structure includes removing the second mask layer and forming the pillar structure in the pattern hole, and
based on a lower surface of the substrate, an upper surface of the pillar structure is positioned at a higher vertical level than a vertical level of a lower surface of the first mask layer.

21-22. (canceled)

23. A method for manufacturing a semiconductor device, the method comprising:
forming a substrate including a chip area and an out-of-chip area;
forming a bit line on the substrate and in the chip area extending across the substrate;
forming a buried contact between the bit lines and connected to the chip area of the substrate;
forming a landing pad on the buried contact;
forming a step key on the substrate and in the out-of-chip area;
forming a mold layer on the chip area and the out-of-chip area covering the landing pad and the step key;
forming a first mask layer on the mold layer, wherein the first mask layer includes a metal material;
forming a key-hole in the first mask layer overlapping the step key;
forming a transparent layer in the key-hole;
forming a second mask layer on the first mask layer and the transparent layer while aligning the second mask layer using the step key;
etching the mold layer in the chip area using the second mask layer to form a pattern hole;
forming a lower electrode filling the pattern hole; and
forming a dielectric film and an upper electrode on the lower electrode,
wherein:
a light transmittance of the transparent layer is greater than a light transmittance of the first mask layer, and
a first vertical level of an upper surface of the lower electrode extends farther in a vertical direction relative to a bottom surface of the substrate than a second vertical level of an upper surface of the mold layer.
